(19) United States
(12) Patent Application Publication
(10) Pub. No.: US 2026/0040701 A1
(43) Pub. Date: Feb. 5, 2026

(54) ANALOG IN-SENSOR VISION PROCESSING ARRAYS

(71) Applicant: University of Massachusetts, Westborough, MA (US)

(72) Inventor: Guangyu Xu, Lexington, MA (US)

(73) Assignee: University of Massachusetts, Westborough, MA (US)

(21) Appl. No.: 19/286,342

(22) Filed: Jul. 31, 2025

Related U.S. Application Data
(60) Provisional application No. 63/677,449, filed on Jul. 31, 2024.

(51) Int. Cl. H10F 39/18; H10F 30/221; H10F 39/00

(52) U.S. Cl. CPC H10F 39/18; H10F 30/221; H10F 39/014; H10F 39/803; H10F 39/811

(57) ABSTRACT

Scalable in-sensor visual processing arrays of dual-gate amorphous-silicon photodiodes, which are used for multiplexed event sensing at sub-ms precision and edge detection of multiple objects, respectively. Both arrays are built in ca. 200-μm pitches and consume zero static power via their bias conditions; their analog output directly captures the amplitude of event-driven light changes and light intensities on the object edges without complex digitization circuits. Capable of processing both temporal and spatial visual information, these arrays emulate the signaling pathways in the human retina, suggesting a path towards large-scale analog in-sensor visual processing systems.

### CROSS-REFERENCE TO RELATED APPLICATIONS

This patent document claims priority to earlier filed U.S. Provisional Patent Application Ser. No. 63/677,449, filed on Jul. 31, 2024, the entire contents of which are incorporated herein by reference.

### STATEMENT REGARDING FEDERALLY SPONSORED RESEARCH OR DEVELOPMENT

This invention was made with government support under National Science Foundation Grants ECCS 2046031, ECCS 2055457, and CCF 2133475. The government has certain rights in the invention.

### BACKGROUND OF THE INVENTION

### 1. Field of the Invention

The present patent document is directed generally to computer vision, and more particularly to embedded computer vision processing arrays.

### 2. Background of the Related Art

Computer vision, capable of automated acquirement, perception, and analysis of visual information, has become an increasingly significant technology in autonomous navigation¹, object recognition², bioimaging^{3,4}, and human-machine interfacing⁵. Yet, the ubiquity of time-sensitive and data-intensive computer vision tasks brings a growing challenge for existing vision systems, which often involve exchanging redundant data between physically separated sensing and computing units. From this perspective, in-sensor processing of either static or dynamic visual information may represent a viable hardware approach to lessen the latency and energy consumption spent over the data exchange by integrating sensing and pre-processing units at the device level^{6,7}. Such in-sensor processing hardware emulates the way the human retina⁸⁻¹¹ acts to extract spatial features¹²⁻¹⁶ (e.g., edges) and trace temporal changes^{1,17-21} (e.g., motion). It has brought interest in developing peripheral integrated circuits²²⁻²⁵, visual perception/analysis algorithms^{26,27}, and intelligent systems^{2,13-15,18,27,28}.

Among burgeoning bio-inspired in-sensor visual processors, gate-tunable photodetectors built from crystalline silicon (Si)²⁹, ferroelectric materials³⁰, or two-dimensional (2D) heterostructures^{1,13,15,16,19,31} are well suited for large-scale visual processing, because their planar morphology lends themselves to top-down fabrication of processor arrays with parallel readout. These devices are fundamentally different from conventional practice in visual processing with low filling factors (FF) and high power consumption^{21,22,32}, where photodetector-acquired data need to be computed by in-pixel/peripheral circuits^{12,17,20}, graphics processing units (GPU)³², or field-programmable gate arrays (FPGA)²². Moreover, their visual processing is achieved in the analog domain, where gate-tunable photoresponsivity (Rₚₕ) is taken as the weight for multiply-accumulation computation^{27,29,33}. Nonetheless, most of these pioneering works have been limited to the single-device level, and are rarely tested for both static and dynamic visual processing³³. To advance towards large-scale visual processing systems, it is imperative to develop scalable, compact, and low-power arrays to extract static features and detect dynamic events with a high degree of parallelism³³. This is a non-trivial task as it requires a holistic modular-array co-design that needs to be routed in a compact layout (for high FFs) and operated in an energy-efficient manner (for low-power operation).

Accordingly, there is a need in the prior art for computer vision processing arrays.

### SUMMARY OF THE INVENTION

Here we report, based on dual-gate amorphous-silicon photodiodes (α-Si PDs), two scalable in-sensor visual processing arrays (in ca. 200-μm pitches) for multiplexed event sensing at <1 ms precision and parallel edge detection of multiple objects, respectively. The choice of α-Si PDs as the processing units assures their compatibility with large-scale array fabrication. Both arrays consume zero static power by short-circuit operations; their analog output (programmed by gate biases) directly quantifies event-driven light changes (i.e., temporal visual processing) and light intensities on the edge of light spots (i.e., spatial visual processing) in the absence of in-pixel/peripheral circuits, thereby resulting in FFs as high as 30% and 90%, respectively.

Specifically, the first array integrates PDs, resistors, and one capacitor as the in-senor computing unit (CU) for event sensing. These CUs respond to the change of optical power density (ΔP_{light}) with transient spikes (within 1 ms), whose amplitudes are gate-tunable and increase with ΔP_{light}. Subsequently, we demonstrate a two-by-two cross-barred CU array to detect location-dependent events provided by independent light sources. On the other hand, the second array parallelizes three-by-three PDs as an image kernel for in-sensor edge detection. These kernels identify the edges of objects by convolutional filtering, whose photocurrents (Iₚₕ) are gate-tunable and increase with optical power density (P_{light}) applied on the edge of a light spot. Subsequently, we demonstrate an eight-by-eight kernel array (comprised of 576 PDs) for parallel edge detection of single and multiple objects. Emulating the human retina, our PD-based arrays achieve analog in-sensor processing of both temporal and spatial visual information, suggesting a path towards low-power, large-scale in-sensor visual processing systems with high throughput.

### BRIEF DESCRIPTION OF THE DRAWINGS

These and other features, aspects, and advantages of the present invention will become better understood with reference to the following description, appended claims, and accompanying drawings where:

FIGS. 1A-1E is a miniaturized dual-gate silicon photodetectors with gate-tunable photoresponse according to the present disclosure, where FIG. 1A shows a dual-gate α-Si PD (top) with its zoom-in view (middle) and cross-sectional structure (bottom), (scale bar, 100 μm);

FIG. 1B shows I_{S}-V_{S} curves measured in dark with V_{G1}=−V_{G2}=3 V (left) and −3 V (right); the inset shows their associated the band diagrams at V_{S}=V_{D}=0 V; FIG. 1C shows Contour plots of short-circuited Iₚₕ values measured with V_{G1} and V_{G2} ranging from −3 to +3 V, P_{light}=35 mW/cm² centered at 595 nm; FIG. 1D shows the Iₚₕ-Vₚ curve measured at V_{S}=V_{D}=0 V, P_{light}=35 mW/cm² centered at 595 nm; and FIG. 1E shows Iₚₕ-P_{light} curves measured at V_{S}=V_{D}=0 V, with Vₚ ranging from −3 to 3 V at a 1 V step, P_{light}=0-35 mW/cm² centered at 595 nm;

FIGS. 2A-2D is an illustration of pairing dual-gate photodetectors for analog in-sensor event detection, where FIG. 2A shows a single CU (left) and its equivalent circuit (right) (scale bar, 100 μm); FIG. 2B shows CU response to 550/15 nm light pulses (ΔP_{light}=530 mW/cm², tₒₙ/t_{off}=90/130 ms, three 20-pulse periods); FIG. 2C shows Vₚ-dependence of |Aₒₙ|, |A_{off}|, tᵣᵢₛₑ, and t_{fall} of a single CU extracted from its Vₒᵤₜ traces; the light pulsing condition in FIG. 2B is repeated here (ΔP_{light} is fixed at 530 mW/cm²); and FIG. 2D ΔP_{light}-dependence of |Aₒₙ|, |A_{off}|, tᵣᵢₛₑ, and t_{fall} of a single CU extracted from its Vₒᵤₜ traces (Vₚ is fixed at 2.5 V); ΔP_{light} ranges from 53 (1%) to 530 (10%) mW/cm², while the rest of the light pulsing condition is the same as FIG. 2B, where shaded areas in FIGS. 2B-2D and error bars in FIGS. 2c-2D both represent ±1 standard deviation (S.D.) from a total of 60 pulses in three light pulsing periods;

FIGS. 3A-3E shows a parallel in-sensor event detection using photodetector arrays, where FIG. 3A shows A CU array (left,) and its equivalent circuit (right) (scale bar, 100 μm); FIG. 3B shows an optical setup with two fiber-coupled LEDs; FIG. 3C shows illumination conditions (I-III); FIG. 3D shows Vₒᵤₜ-traces of U11 and U12 under illumination conditions I-III; and FIG. 3E shows |Aₒₙ| and |A_{off}| values detected by U11, U12, U21, and U22 under illumination conditions I-III, where shaded areas in FIG. 3D and error bars in FIG. 3E both represent ±1 S.D. from a total of 60 pulses, and dash lines in FIG. 3E represent the noise level (3 S.D.) calculated from the baseline data of four CUs; and

FIGS. 4A-4G shows a gate-tunable analog in-sensor edge detection at single-kernel and kernel-array levels, where FIG. 4A shows a single kernel (left) and its equivalent circuit (right); FIG. 4B shows a kernel configured as a horizontal Prewitt filter (left) is used to detect the edges of a horizontally moving light spot (P_{light}=530 mW/cm² at 550/15 nm) based on Vₒᵤₜ values measured at a ca. 23 μm step (right); FIG. 4C shows a kernel array (left) and its schematics (right); and FIGS. 4D-4G show parallel in-sensor edge detection of one aperture-defined light spot (FIGS. 4D and 4E) and two shadow-mask-defined light spots (FIGS. 4F and 4G) using the kernel array (P_{light}=530 mW/cm² at 550/15 nm), where the combined map of Vₒᵤₜ (i.e. contour plots) across the array are calculated from the two maps of Vₒᵤₜ measured when all 64 kernels are configured as a horizontal and a vertical Prewitt filter, respectively (FIGS. 4E and 4F) (scale bars in FIGS. 4A, 4C, 4D, and 4F, 100 μm. In FIG. 4D and 4F, dash lines depict the location of each kernel, including the one in the center of the light spot(s) and its adjacent neighbors);

FIGS. 5A and 5B show illustrations of fabrication flow of a single PD (FIG. 5A) and its 3D schematics (FIG. 5B).

FIG. 6 shows an illustration of PDs with an even number of channels have a less effect of alignment error on their photoresponse. The alignment error of S/D-contacts (e.g. the S-[D-] contact is accidentally formed closer [further] to the G1[G2]-contact of the 1^{st} channel) brings asymmetry of the p- and n-doped areas in each channel. Such asymmetry in an even number of channels cancels each other when V_{G1}=−V_{G2}, leading to a symmetric Vₚ-Iₚₕ curve in FIG. 1D. Scale bar, 10 μm.

FIG. 7 shows an illustration of COMSOL simulation of electron and hole concentration profiles (log scale) in shot-circuited PDs.

FIG. 8 shows an illustration of I_{S}-V_{S} curves of a single PD when V_{G1}=V_{G2}=−3 or 3 V and that when both G1- and G2-contacts are floated (P_{light}=530 mW/cm² at 550/15 nm).

FIG. 9 shows an illustration of Iₚₕ-P_{light} curves and their zoom-in view obtained from another PD (Vₚ ranging from −3 to 3 V at a 1 V step, P_{light}=0.83-1696 mW/cm² at 550/15 nm), suggesting a ca. 10³ dynamic range with good linearity (R²>0.98). This specific experiment is conducted differently from that in FIG. 1E. To quantify the dynamic range, weak P_{light} is provided by applying up to 512-time attenuation in the light path of the microscope via neutral-density filters. To measure small-valued Iₚₕ under weak P_{light}, the PD (wirebonded on the loading PCB) has its gate biases offered by the gating PCB, its D-contact biased at 0 V (via SMU), and its S-contact connected to the positive input of the TIA. The negative input of TIA is biased at 0 V to amplify the short-circuited Iₚₕ to Vₒᵤₜ values (low-noise mode, gain=2×10⁹ V/A), which are then filtered by the noise eliminator and sampled by the digital oscilloscope at 10 KHz.

FIGS. 10A and 10B show illustrations of a detailed fabrication flow of a single CU (FIG. 10A) and its 3D schematics (FIG. 10B).

FIG. 11 shows an illustration of Vₒᵤₜ-traces from the 1R1C [1R] branch (left [right]) of a single CU. The light spot (pulsing with ΔP_{light}=530 mW/cm² at 550/15 nm, same in FIG. 2B) is spatially confined to the PD in the select branch. Shaded areas represent ±1 S.D. from a total of 60 pulses.

FIGS. 12A and 12B show illustrations of LTspice simulation of tᵣᵢₛₑ and t_{fall} in a single CU with various R₁, R₂, and C values., where FIG. 12A shows equivalent circuit and extracted tᵣᵢₛₑ and t_{fall} with Rₚ=100 GΩ, Rₛ=0 (neglected), and Cⱼ=12 pF, and FIG. 12B shows equivalent circuit and extracted tᵣᵢₛₑ and t_{fall}. with Rₚ=100 GΩ, Rₛ=100 kΩ, and Cⱼ=12 pF. Here we send current pulses to the ideal current source to emulate the photoresponse of a single CU; one 1 nA current pulse (t_{on/off}=50/50 ms) is configured to switch between its 10 and 90% amplitude within 1 ns. In both FIGS. 12A and 12B, we set V_{G1}=−V_{G2}=2.5 V, C_{G1-S}=C_{G2-D}=5 pF.

FIG. 13 shows an illustration of schematics of a CU array.

FIG. 14 shows an illustration of a circuit diagram of the CU experiments.

FIGS. 15A-15C show illustrations of spike numbering of the CU array for illumination conditions I-III, respectively.

FIGS. 16A-16D show illustrations of |Aₒₙ| and |A_{off}| values detected by U11, and U12 under conditions I and II, with 2 PDs in the CU being biased at V_{p_H} [V_{p_L}] to let each branch output Vₒᵤₜ=±60 mV [40 mV] (see also FIG. 24B); where spikes are numbered in FIG. 16A and 16B; error bars in FIGS. 16C and 16D represent ±1 S.D. from a total of 60 pulses; and dashed lines in FIG. 16C represent the noise level (3 S.D.) calculated from the baseline data of each CU.

FIG. 17A-17C shows an illustration of crosstalk analysis when two separate CUs are connected in the same way as U12 (FIG. 17A) and U21 (FIG. 17B) are connected to U11 in the array, respectively; where FIG. 17A shows two separate CUs on the same chip. Scale bar, 100 μm. FIGS. 17B and 17C show |Aₒₙ| and |A_{off}| values detected by U1 and U2 when light pulses (ΔP_{light}=530 mW/cm² at 550/15 nm, tₒₙ/t_{off}=90/130 ms; three 20-pulse periods) are spatially confined to only one of the two CUs. Shaded areas and error bars both represent ±1 S.D. from a total of 60 pulses.

FIGS. 18A-18D show illustrations of LTspice simulation of the crosstalk from two connected CUs, where PDs are modeled the same way as shown in FIG. 14.

FIGS. 19A and 19B show illustrations of fabrication flow of a kernel (FIG. 19A) and its 3D schematics (FIG. 19B).

FIG. 20 shows an illustration of a kernel configured as a vertical Prewitt filter (left, see Vₚ values in FIG. 26) is used to detect the edges of a vertically moving light spot (P_{light}=530 mW/cm² at 550/15 nm) based on Vₒᵤₜ values measured at a ca. 23 μm step (right).

FIG. 21 shows an illustration of circuit diagram of the kernel experiments.

FIG. 22 shows an illustration of PD readout at Vₚ=−3 V and 3 V from four kernels in the center of a kernel array, where bars represent nine PDs in each kernel; error bars represent ±1 S.D. from four kernels.

FIG. 23 shows an illustration of P_{light}-dependence of the readout of a kernel array configured for in-sensor edge detection, where experiments in FIGS. 4D and 4E are repeated with P_{light}=265 mW/cm² (5%), 530 mW/cm² (10%), and 1060 mW/cm² (20%) at 550/15 nm. Bars represent the positive- [negative-] maximum readout in each Vₒᵤₜ heat map.

FIGS. 24A and 24B show illustrations of an experimental setup, where FIG. 24A shows an exemplified testing setup for single CUs and the CU array, and FIG. 24B shows a block diagram of the testing setup.

FIGS. 25A-25D show illustrations of Vₚ-dependence of Vₒᵤₜ values from a CU (FIG. 25A), a representative CU in a CU array (FIG. 25B), and a representative PD from a kernel (FIG. 25C) and a kernel array (FIG. 25D). For each branch, we first sweep Vₚ for five consecutive 0→3→0 V cycles, followed by five consecutive 0→+3→0 V cycles. The squared half cycle (in which we believe the PD has reached to its steady state) is chosen to decide the value of Vₚ needed to output targeted Vₒᵤₜ values (e.g. (FIG. 25A) Vₒᵤₜ=±60 mV in FIG. 10A, (b) Vₒᵤₜ=±70 mV in FIG. 3A, (c) Vₒᵤₜ=±400 mV in FIG. 4B, (FIG. 25D) Vₒᵤₜ=±200 mV in FIG. 4D-4G). The light spot (P_{light}=530 mW/cm² at 550/15 nm) is spatially confined to the PD in the select branch (FIG. 25A, 25B), and illuminating the whole kernel/kernel array (FIG. 25C, 25D).

FIG. 26 shows an illustration of Vₚ values used in the CU experiments.

FIG. 27 shows an illustration of Vₚ values used in the kernel experiments, where R1-R3 and C1-C3 represent row and column positions of the PD in the kernel, respectively.

### DESCRIPTION OF THE PREFERRED EMBODIMENT

Modular design of dual-gate α-Si PDs with gate-tunable photoresponse: Leveraging crystalline Si-based dual-gate PDs reported by Jang, H. et al.²⁹, our engineering efforts start from re-designing these gate-tunable p-i-n PDs as the analog visual processing unit with the following improvements (FIGS. 5A and 5B).

First, the photo-sensitive materials of the PDs are different. Instead of building PDs from an intrinsic crystalline silicon substrate, here we deposit intrinsic α-Si films on top of a SiO₂/Si wafer (sandwiched by oxide and metallization layers, see Methods) to form photo-sensitive regions of the diode. This PD structure is chosen for the high absorption coefficient of α-Si (vs. crystalline Si) and its compatibility with monolithic integration onto complementary metal-oxide-semiconductor (CMOS) chips (vs. intrinsic Si substrate).

Second, the FF of PDs is increased. Different from prior Si-based PDs²⁹ in which interdigitated gate contacts are placed on the backside of the gate oxide and the source/drain (S/D-) contacts on top, the S/D-contacts of our α-Si PDs are below the α-Si films. As a result, there are no metal wires on top of the α-Si films, allowing for full exposure to the incident light and, hence an increased FF.

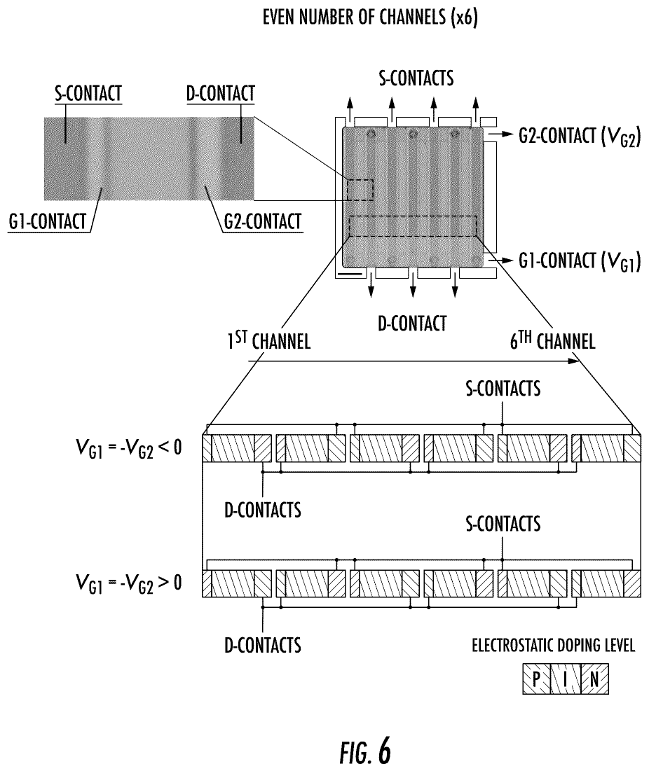

Third, the device layout is more error tolerant. Here we purposely choose an even number of light-absorbing channels between each pair of S- and D-contacts. This geometry serves to minimize the dependence of the photoresponse on the possible asymmetric electrostatic doping effect caused by alignment error of gate contacts (FIG. 6), thus keeping a similar range of the absolute photoresponse values when the two gate biases flip their polarities at the same time.

Lastly, the PD dimension is scaled down to save the chip area. As the modular design towards compact visual processing arrays, we choose to reduce the size of the active region in each PD down to ca. 70-80 μm, and the channel width/length ratio down to ca. 400-470/5 μm (vs. 300 μm and 5576/5 μm in Ref. 29).

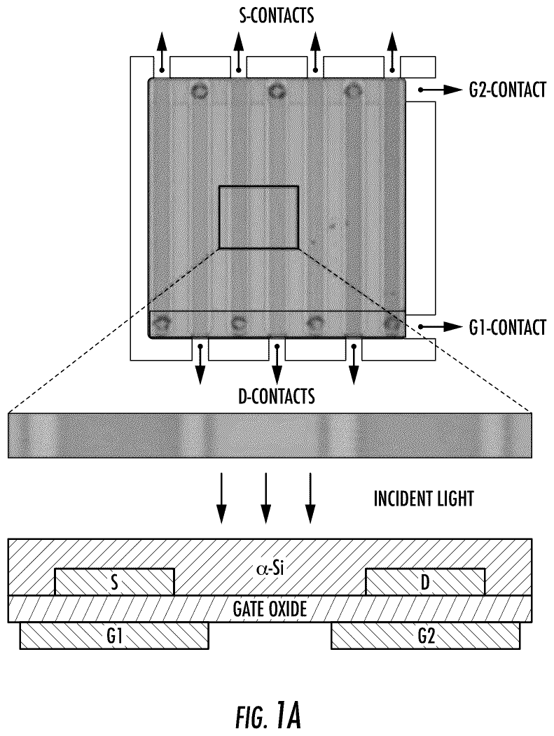

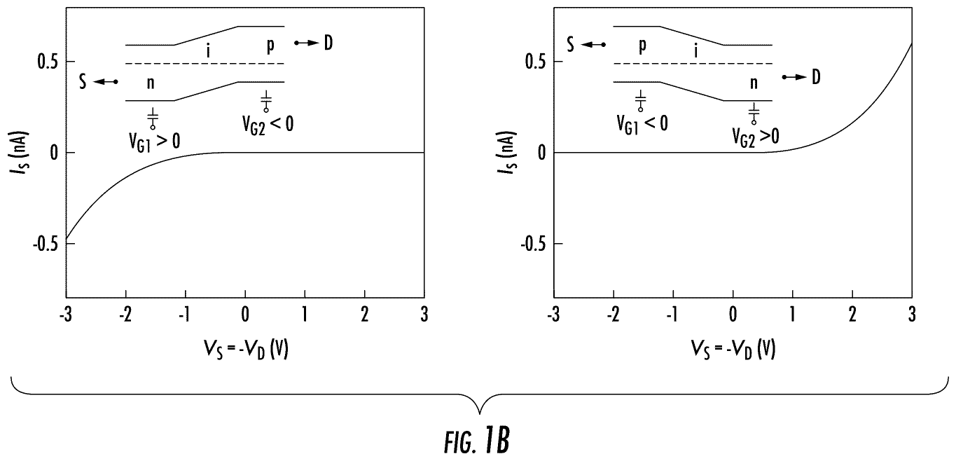

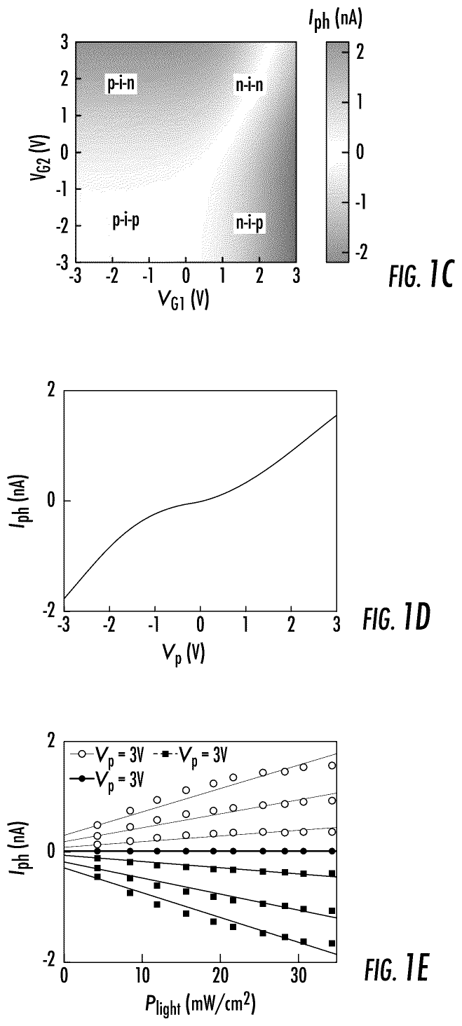

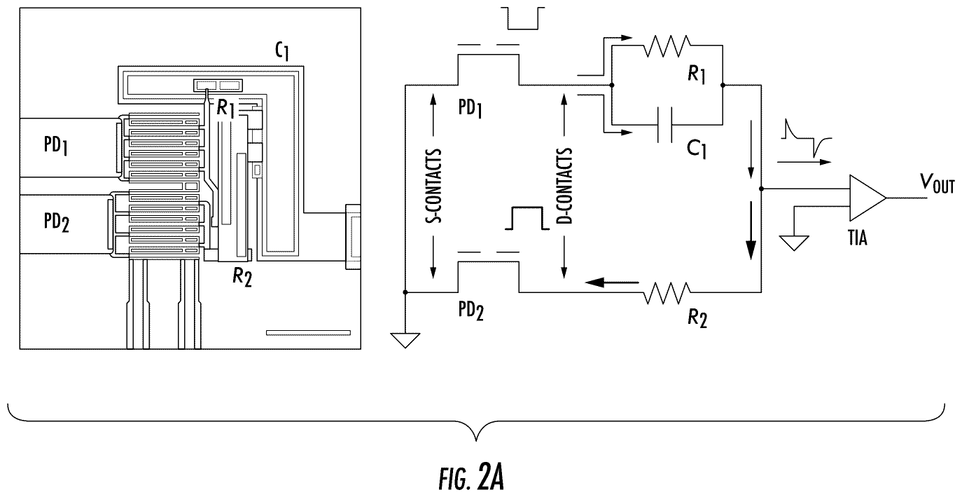

Fabrication of individual α-Si PDs: With the foregoing design considerations, we first form gate-routing lines by sputtering Ti/Pt layers (10/50 nm) on top of a SiO₂/Si substrate (Methods) and passivate them with a 300-nm SiO₂ layer deposited by plasma-enhanced chemical vapor deposition (PECVD). Next, we form Cr/Au-based vias (10/300 nm) through this passivation layer (by via opening and metallization steps) and connect them with two interdigitated gate contacts in the shape of multi-fingers (G1 and G2, the finger pitch [finger width] is 15 μm [ca. 70-80 μm]) based on sputtered Ti/Pt layers (10/50 nm). We then use an atomic layer deposition (ALD) step to form an Al₂O₃-based gate oxide layer (ca. 30 nm), followed by making S-and D-contacts on top (10/50 nm Ti/Pt layers). These S- and D-contacts are centered to G1- and G2-contacts, respectively, but chosen to be 2-μm narrower; this device geometry assures that G1 [G2] can create electrostatically doped regions surrounding S[D]-contacts (FIG. 1a). We then deposit a PECVD-based intrinsic α-Si film (ca. 250 nm) on top of the S- and D-contacts, and pattern it into the active region of the PD. The entire device is finally passivated by a PECVD-SiO₂ layer (ca. 300 nm), and routed to wire-bonding pads with Ti/Pt layers (10/100 nm).

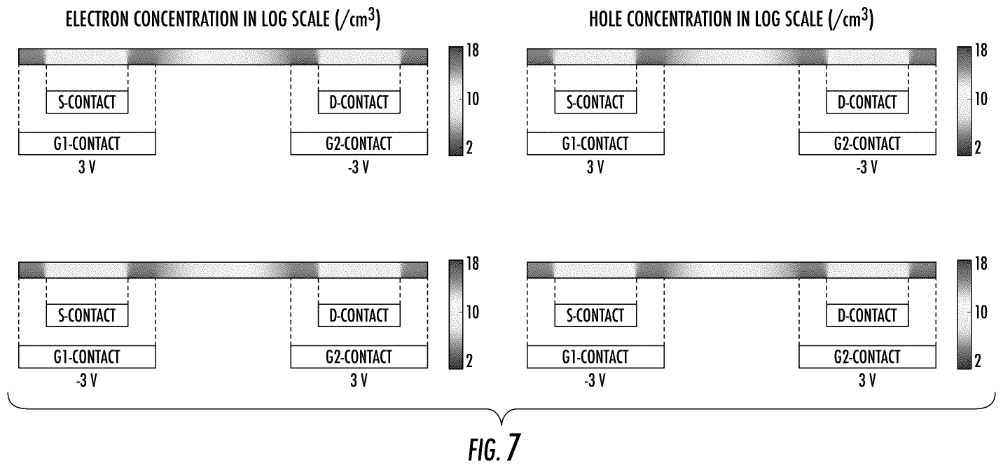

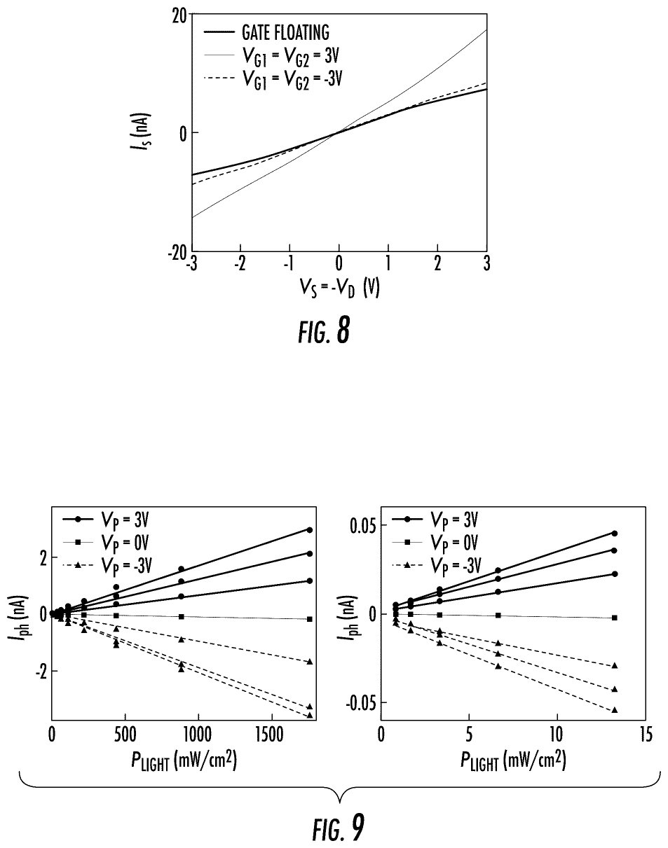

Optoelectronic characteristics of as-made PDs: Our dual-gate PD structure serves to alter both the direction and the amplitude of diode current by two independent gate biases (V_{G1} and V_{G2} on G1- and G2-contacts) via gate-induced electrostatic doping effect in the α-Si film. To assess such electrostatic doping effects^{29,34-36} in our PDs, we set the two gate biases as V_{G1}=−V_{G2}=3 or −3 V, and measured the source current Is in the dark when V_{S}=−V_{D} was swept from −3 to 3 V at a step of 50 mV (FIG. 1). In this configuration, the field effect from the positively [negatively] biased gate will create n-type [p-type] electrostatic doping profiles in the α-Si regions above them. The measured I_{S}-V_{S} curves are rectified with a turn-on voltage at ca. 0.7 or −0.7 V, suggesting the existence of electrostatically doped p-i-n/n-i-p regions between S- and D-contacts (consistent with simulation results in FIG. 7). Next, under constant optical power density (P_{light}=530 mW/cm² at 550/15 nm) I_{S}-V_{S} curves measured at V_{G1}=V_{G2}=3 or −3 V feature higher Is values than those measured with floated G1 and G2 (FIG. 8), possibly because the gate-induced p-i-p/n-i-n doping profile reduces the channel resistance³⁷; these linear I_{S}-V_{S} curves also suggest insignificant Schottky barriers near S-and D-contacts^{35,36}.

We next investigate gate-dependence of the Iₚₕ in our PDs (i.e. the I_{S} under light illumination subtracted by that in the dark), which is an essential figure of merit for in-sensor visual processing^{6,7,13}. To this end, we map short-circuited/ph values (i.e. measured at V_{S}=V_{D}=0 V, P_{light}=35 mW/cm² at 595 nm) with V_{G1} and V_{G2} being swept from −3 to +3 V at a step of 200 mV, and identify four distinct operation regions on the map (FIG. 1C):
(I) n-i-n and p-i-p regions when V_{G1} and V_{G2} are nearly equal. These two regions show low Iₚₕ values because the built-in potentials across n-i [p-i] and i-n [i-p] junctions cancel each other. These regions are noted to deviate from the diagonal line, V_{G1}=V_{G2}, which can result from charge-trapping defects within α-Si films or near the surface of the gate-oxide layer²⁹ (requiring extra gate biases to dope the channel). The Iₚₕ values in the p-i-p region are lower than those in the n-i-n region, likely because the work function of S/D-contacts (Ti/Pt) is closer to the conduction band edge of α-Si^{35,36}.
(II) n-i-p and p-i-n regions when V_{G1} and V_{G2} are nearly opposite to each other. In these two regions, Iₚₕ monotonically increases from a negative maximum to zero, and further increases to a positive maximum along the negative diagonal line, V_{G1}=−V_{G2}=Vₚ from −3 to 3 V. This trend follows the sum of the built-in potential across n-i [p-i] and i-p [i-n] junctions, which decreases its amplitude to zero when Vₚ changes from −3 to 0 V, then flip its sign and increase its amplitude when V_{G1} changes from 0 to 3 V. Such gate-tunability of/ph (FIG. 1D)—in terms of its direction and amplitude—is the key feature of our PDs for analog visual processing; for the rest of this work, we always gate them as V_{G1}=−V_{G2}=Vₚ.

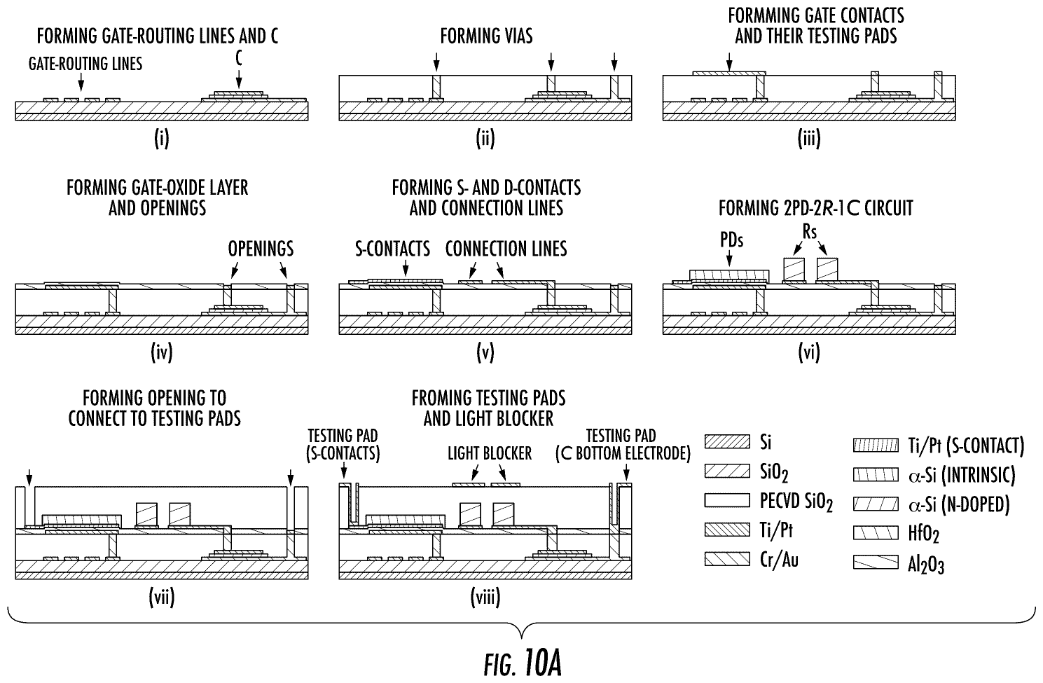

Finally, we examine the linearity of our PDs biased at various Vₚ values (P_{light}=0-35 mW/cm² centered at 595 nm, FIG. 1E; see also FIG. 9). Our results show that Iₚₕ linearly increases with P_{light} (R²>0.91) for P_{light} up to 25 mW/cm² and starts to saturate at higher P_{light} due to the limited carrier lifetime of α-Si that may occur at a high density of photoinduced carriers³⁸. When Vₚ changes from −3 to 3 V, the slope of Iₚₕ-P_{light} curves increases from a negative maximum to a positive maximum, confirming the gate-tunability of Iₚₕ in terms of their polarities and amplitudes.

Pairing dual-gate PDs for analog in-sensor event detection: Event-based vision sensors emulate the human retina to capture the temporal changes of P_{light} (events) in the field of view (FOV). This is in contrast to the frame-based CMOS imagers, which need to achieve visual processing by data-intensive inter-frame differentiation^{21,39} (i.e., comparing P_{light} values across FOV). To date, dynamic vision sensors (DVS) are able to detect the timing of events via binary output, but cannot quantify the value of ΔP_{light}^{17,21,40}. Asynchronous time-based image sensors (ATIS), on the other hand, can digitize ΔP_{light} into discrete values, but at the expense of low FFs due to areas spent on in-pixel circuits^{21,41}. To this end, optoelectronic synaptic devices are capable of analog in-sensor event sensing with high FFs^{14,31,42,43}, but often with a long settling time (seconds). Most recently, 2D-material-based phototransistors⁴⁴ and PDs⁴⁵ are noted for their ultrafast event-detection with ms-and μs-precision, respectively; they unfortunately require the use of off-chip resistors (R) and capacitors (C) to form visual processing nits, thereby presenting a challenge for compact large-scale array integration.

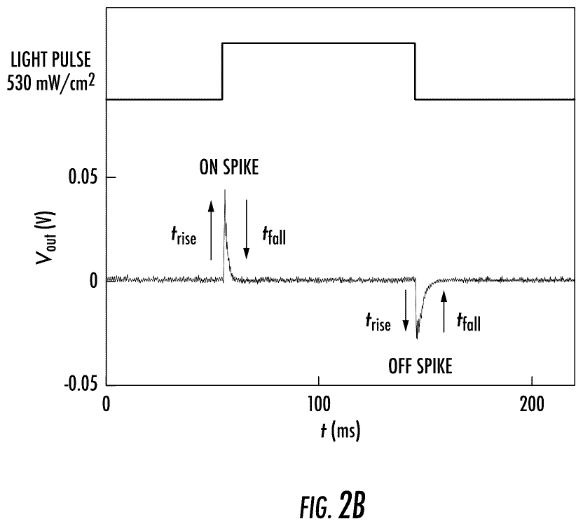

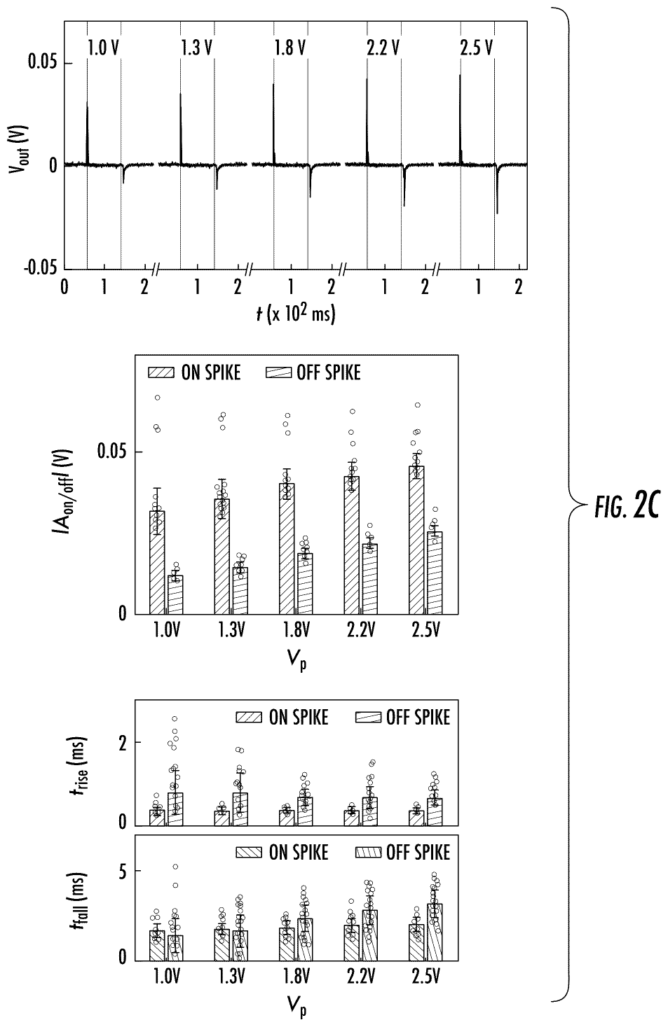

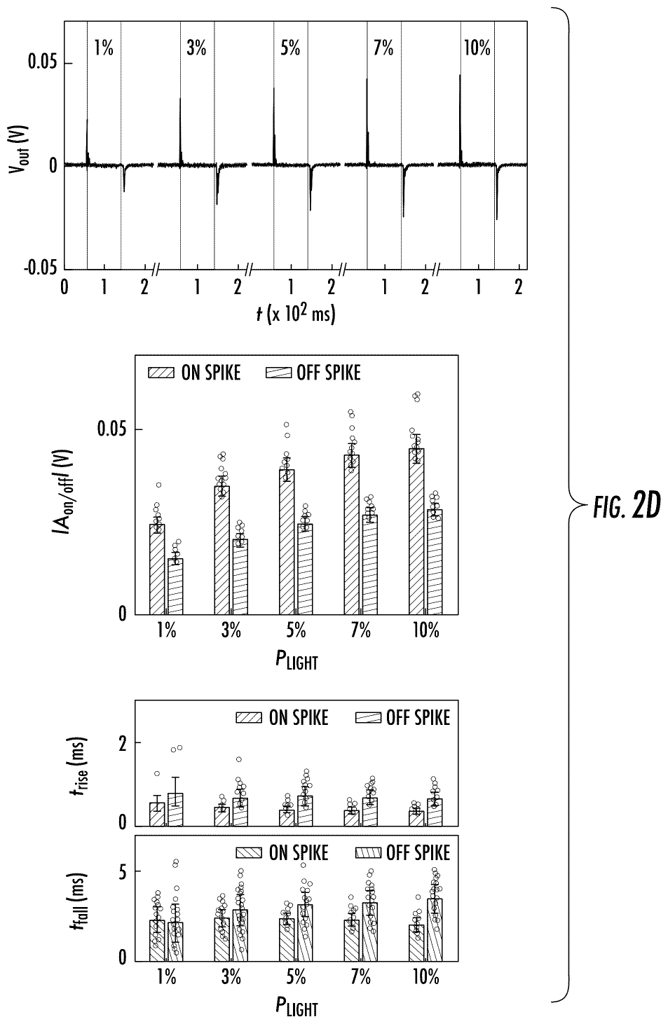

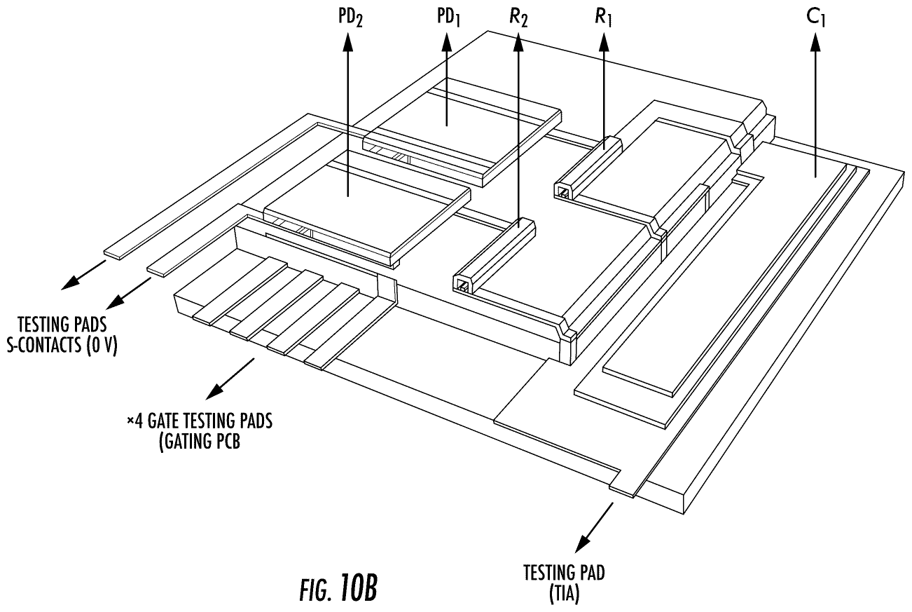

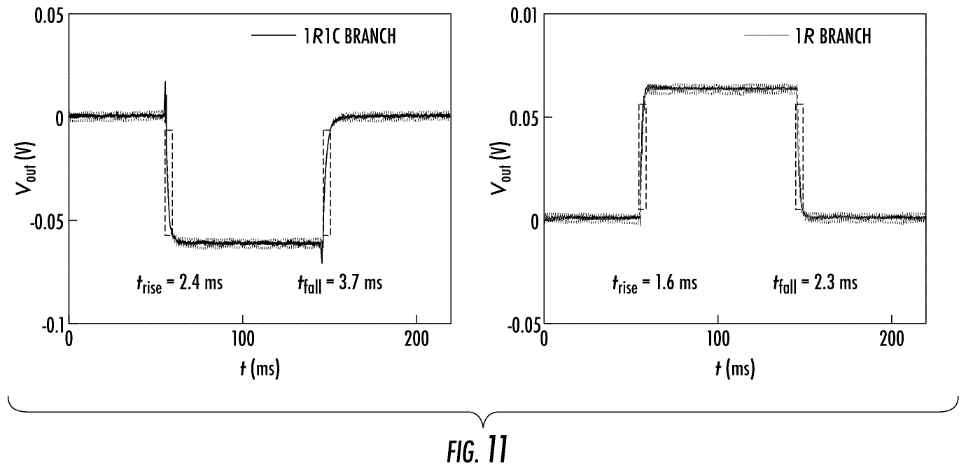

To overcome these limitations, here we leverage our compact, gate-tunable, and low-power α-Si PDs to build an integrated event-based vision processor, showcasing the capability of our PDs for analog in-sensor processing of temporal visual information. To achieve this, we pair up two PDs and connect them with two integrated Rs and one integrated C to form a compact in-sensor CU (i.e. 2PD-2R-1C circuit computing unit, FIG. 2A); R and C are formed by a PECVD-based n-doped α-Si layer (100 nm) and an ALD-based HfO₂ layer (15 nm) sandwiched between metal layers, respectively, and routed to PDs or testing pads (See also FIGS. 10A and 10B).

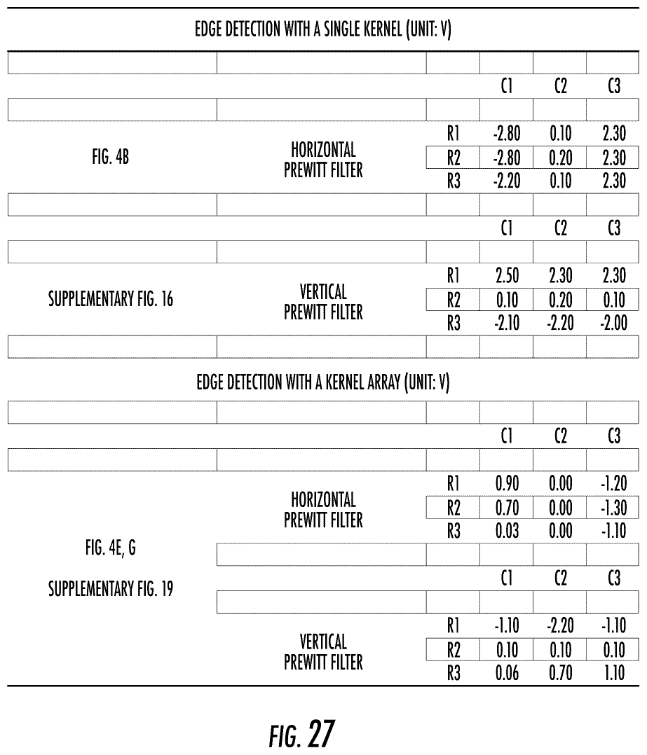

From the circuit perspective, the two α-Si PDs placed in two parallel branches are gated as n-i-p and p-i-n diodes, respectively, leading to the same amount of Iₚₕ that flows to opposite directions (i.e. opposite signs of the photoresponse in FIG. 11, see Vₚ values in FIG. 26); the photoresponse from the 1R1C branch is expected to respond to ΔP_{light} slower than that in the 1R branch due to the extra RC time delay. Moreover, our in-sensor CU consumes zero static power for visual processing¹¹, since both branches are short-circuited by grounding S-contacts of PDs and the input of a trans-impedance amplifier (TIA, FIG. 2A). The net current flows into a TIA—the difference of Iₚₕ in two branches (if any)—converting to a readout voltage Vₒᵤₜ. Under this configuration, our CU outputs zero Vₒᵤₜ when P_{light} is kept as a constant (i.e. no events); when P_{light} changes, the 1R1C branch responds to ΔP_{light} with a latency compared to the 1R branch (exemplified by R₁=R₂=100 MΩ, C₁=100 pF, FIG. 2B), resulting a positive [negative] spike (i.e. ON/OFF spike) when P_{light} increases [decreases]. Such ON/OFF spikes consistently occur near the rising/falling edges of every light pulse we apply (ΔP_{light}=530 mW/cm² at 550/15 nm, tₒₙ/t_{off}=90/130 ms, three independent 20-pulse periods), showing reliable in-sensor event detection.

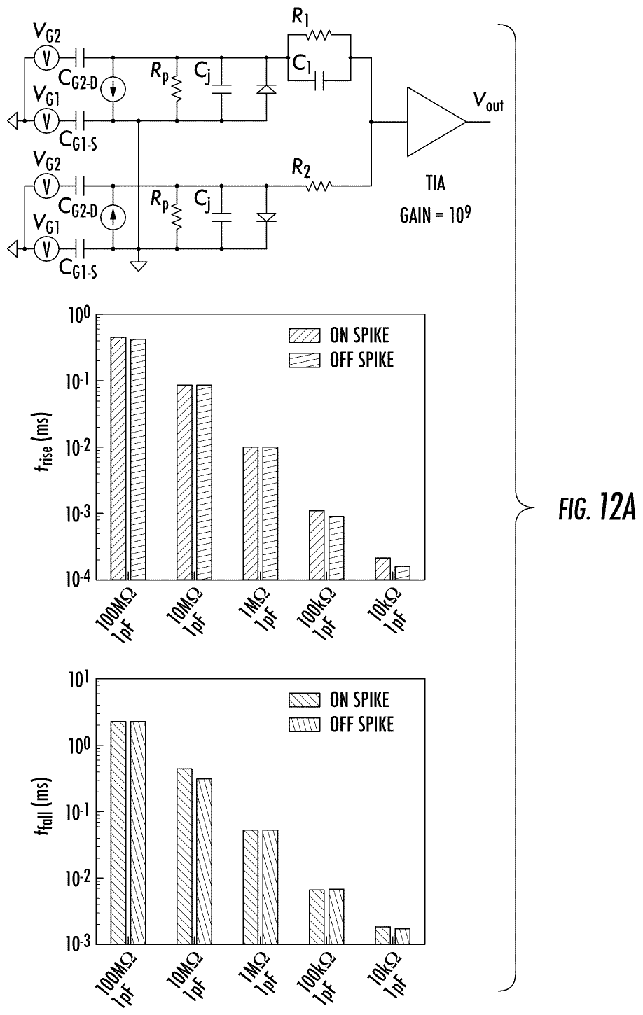

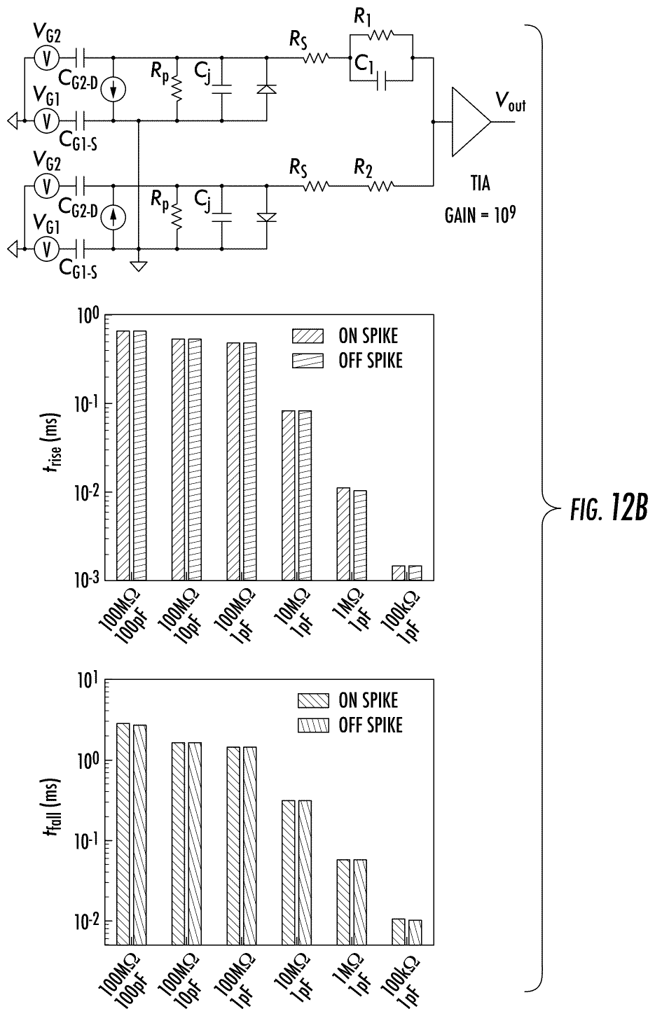

We next characterize the shape of these ON/OFF spikes by varying gate-tunable photoresponse and ΔP_{light}, respectively (see Vₚ values in FIG. 26). With a constant ΔP_{light} (530 mW/cm² at 550/15 nm, tₒₙ/t_{off}=90/130 ms), spike amplitudes, Aₒₙ and A_{off} (defined as positive/negative maximum subtracted by 10-point average in the baseline), are found to increase with Vₚ ranging from 1.0 to 2.5 V (FIG. 2C); with a constant Vₚ, |Aₒₙ| and |A_{off}| are found to increase with ΔP_{light} ranging from 53 to 530 mW/cm² (FIG. 2D). Such Vₚ-and ΔP_{light}-dependent spike amplitudes demonstrate the capability of our CUs for analog in-sensor visual processing; the gate-tunable synapse-like behaviors can be used to form spike neuron network (SNN)^{28,43-45} and develop analog AI chips^{46,47}. On the other hand, the rising [falling] time of these spikes, tᵣᵢₛₑ from 10 to 90% |A_{on/off}| change [t_{fall} from 90 to 10% |A_{on/off}] change] is <1 ms [<5 ms] across all Vₚ and ΔP_{light} values (TIA configured to a high-bandwidth mode). This range of tᵣᵢₛₑ and t_{fall} is on par with the response speed of the human retina¹¹ and suffices the requirement of latency-sensitive applications^{1,4}. If we further reduce RC values (<100 MΩ/100 pF) and increase the bandwidth of TIA (>1 MHz), our CUs can ultimately respond to light pulses with <2 μs tᵣᵢₛₑ and <11 μs t_{fall} due to the small RC delays in our p-i-n/n-i-p PDs (see simulation results in FIGS. 12A and 12B).

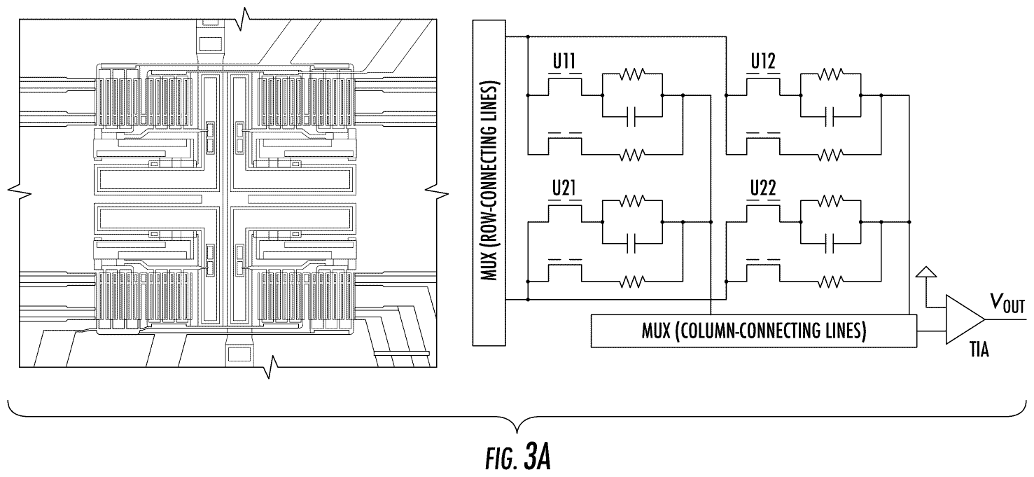

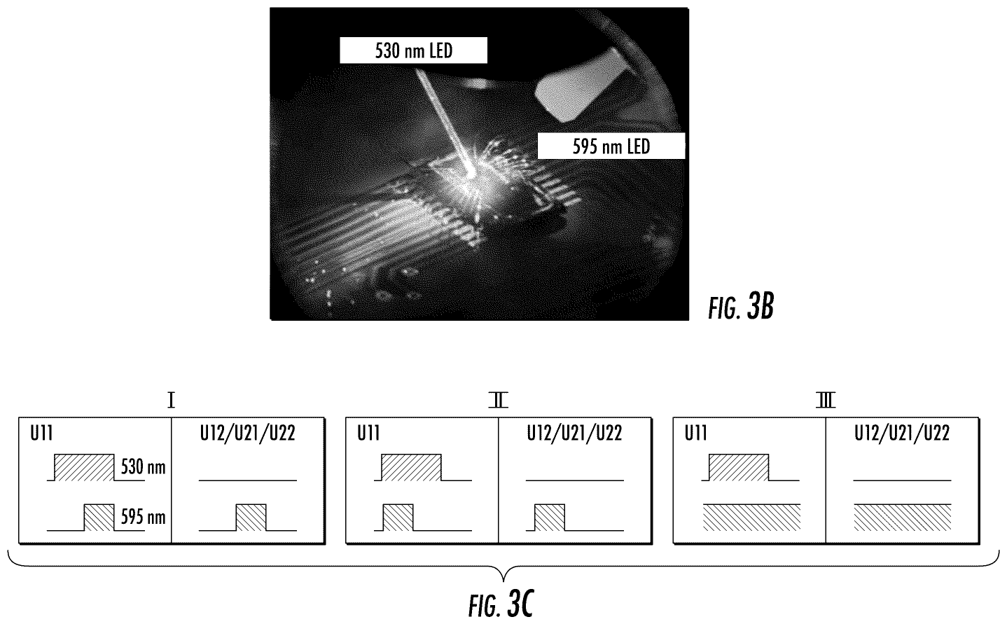

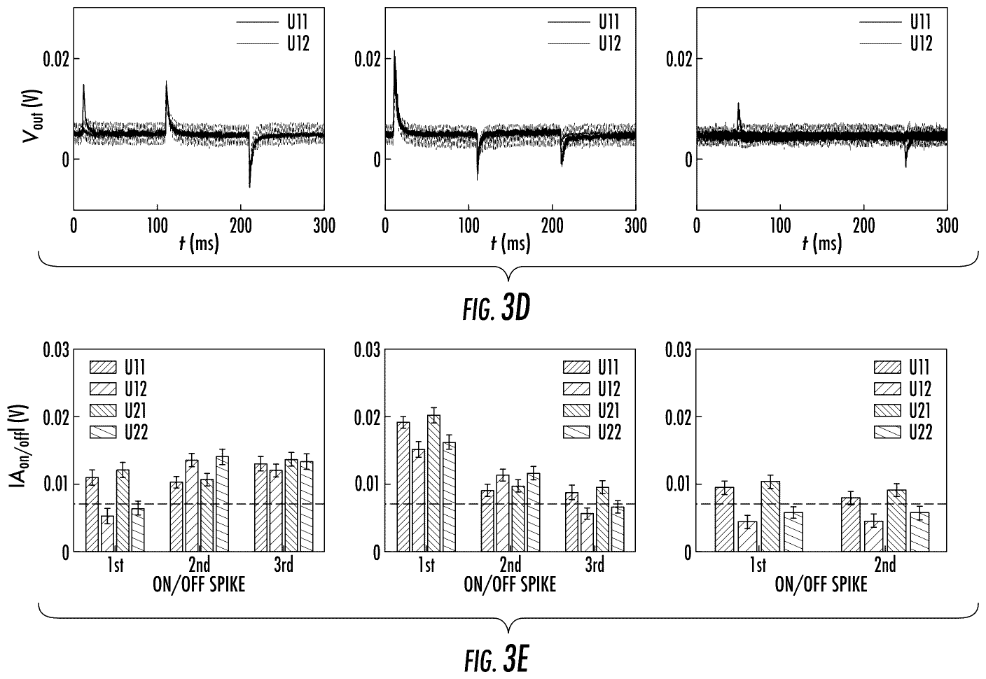

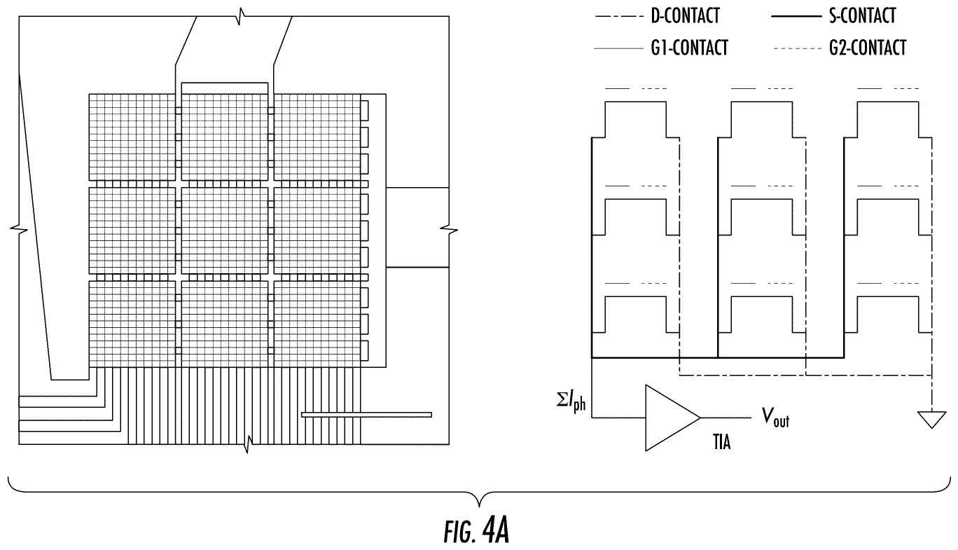

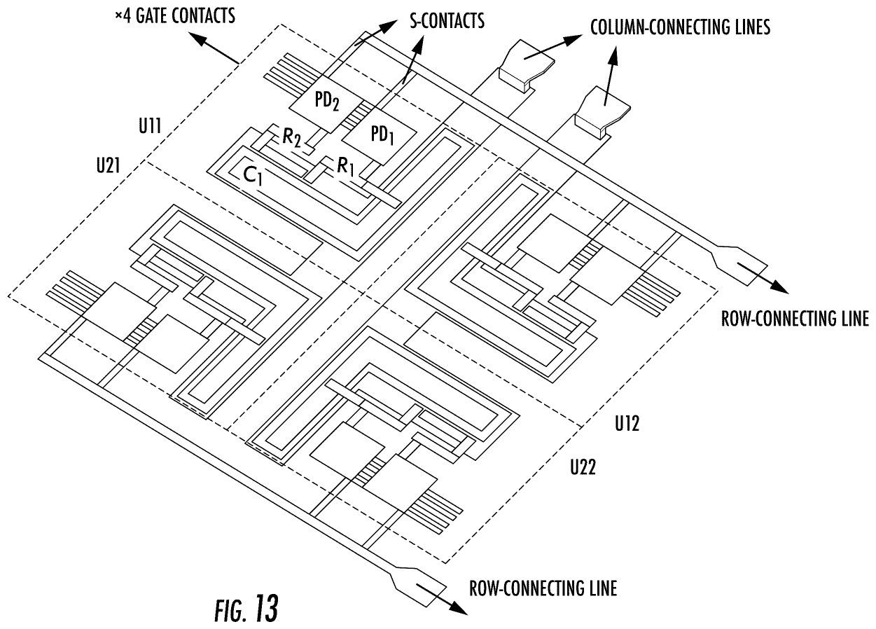

Parallel event detection with in-sensor CU arrays: Leveraging the capability of single CUs, we now take one step further to parallelize such in-sensor event detection at the array level, which is an essential step for large-scale processing of temporal visual information. Specifically, we built a 2-by-2 cross-barred CU array composed of four CUs (U11, U21, U21, and U22, as labeled in FIG. 3A); these CUs are routed to 2 column-connecting lines and 2 row-connecting lines, leaving a total of 16 gate contacts (8 G1- and 8 G2-contacts) that are independently addressable (FIGS. 13 and 14).

To test the array performance, we ground the Si substrate to mitigate capacitive coupling from one CU to the other, which could otherwise cause electrical crosstalk across the array. Four CUs are then gated to output the same amplitudes of Vₒᵤₜ under the same light condition to calibrate out the fabrication variation (see Vₚ values in FIG. 26). Afterwards, we apply spatially nonuniform light illumination to the array by two independent fiber-coupled LEDs (FIG. 3B): a 530 nm LED is applied to illuminate U11 only (tₒₙ/t_{off}=200/100 ms, three 20-pulse periods), while a 595 nm LED is applied to illuminate all four CUs (tₒₙ/t_{off}=100/200 ms, three 20-pulse periods). We then test the array operation with 3 illumination conditions (FIG. 3C): condition I [II] aligns the falling [rising] edge of 530-nm pulses to that of 595-nm pulses; condition III applies constant 595 nm illumination.

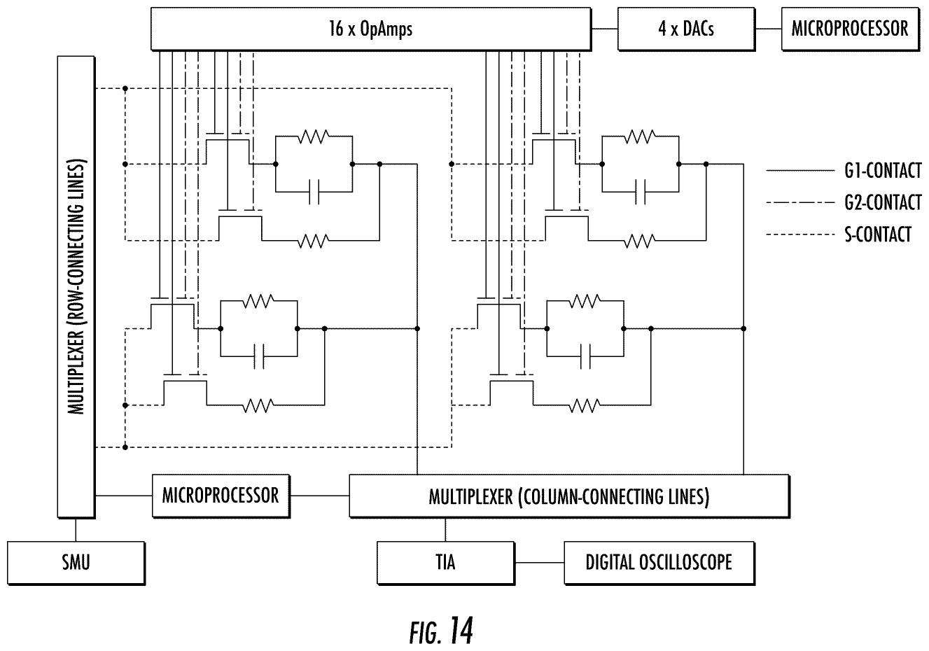

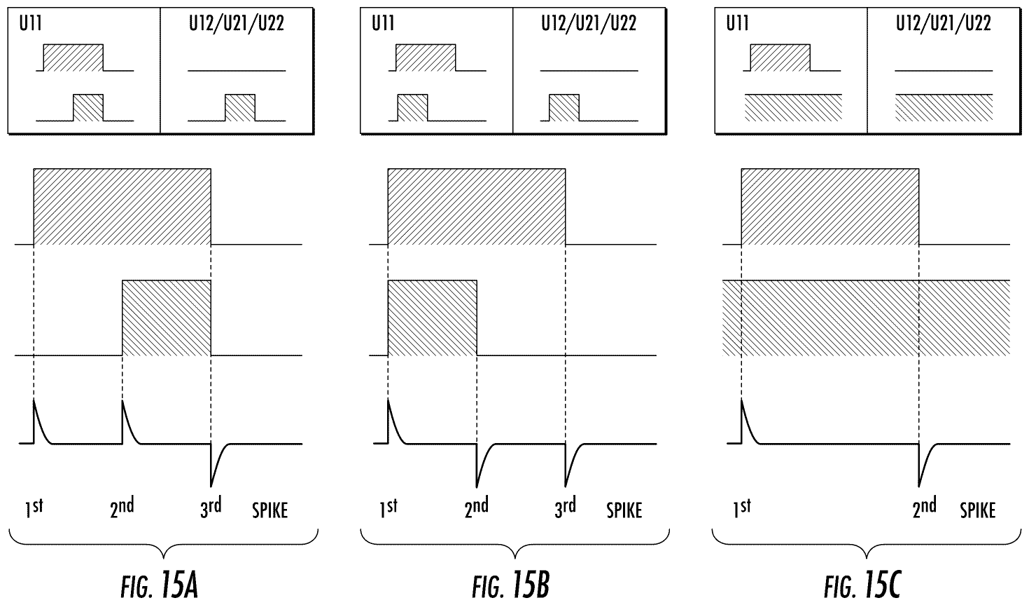

Our experimental data under condition I [II] (taking U11 and U12 as two representative CUs. FIG. 3D) show that: 1) U11 outputs 3 spikes per pulsing period corresponding to both 530- and 595-nm pulses, whereas U12 only outputs 2^{nd} and 3^{rd} [1^{st} and 2^{nd}] spikes corresponding to 595-nm pulses (FIGS. 15A-15C); 2) the amplitude of 3^{rd} [1^{st}] spike from U12 is less than that from U11, in which both 530- and 595-nm pulses are switched off [on]; in contrast, their 2^{nd} spikes have identical amplitudes since 595-nm pulses are applied to U11 and U12. Under condition III, U12 detects no spikes (as expected) since no temporal change of P_{light} is applied here. Together, these results showcase the capability of our array for analog in-sensor processing of location-dependent events; the output amplitudes of four CUs are reliable across all pulsing periods and can be tuned by different Vₚ values (Supplementary FIG. 12).

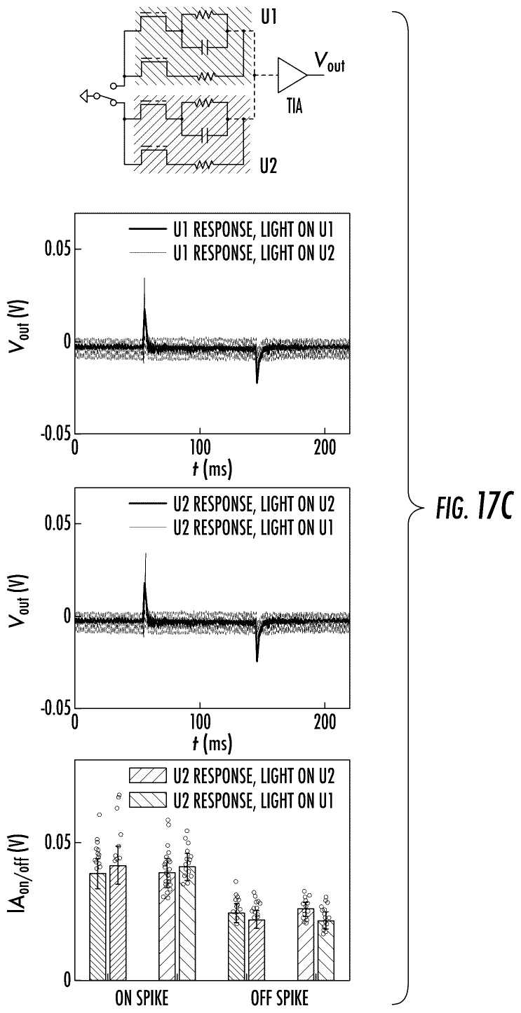

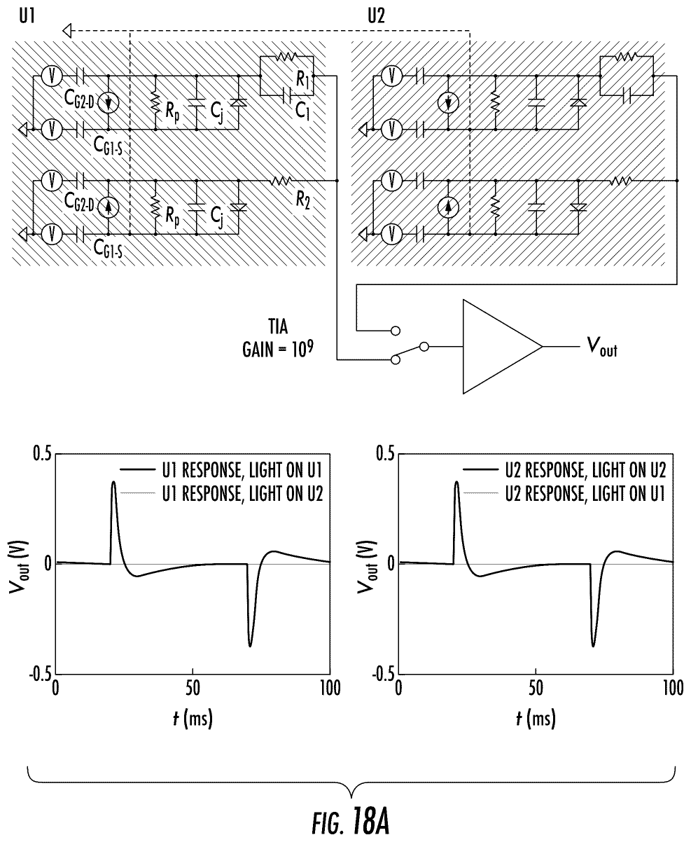

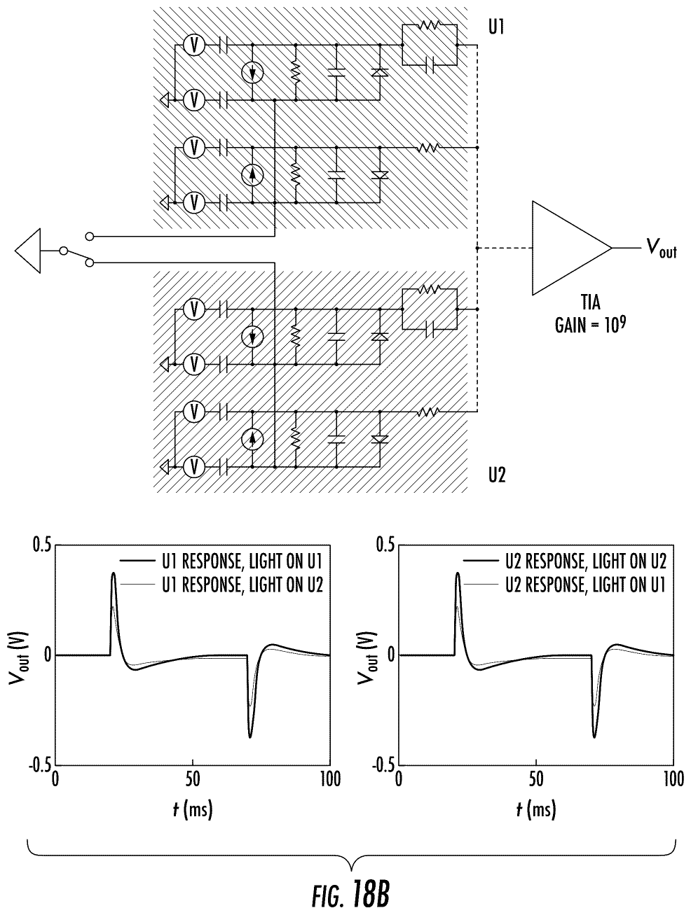

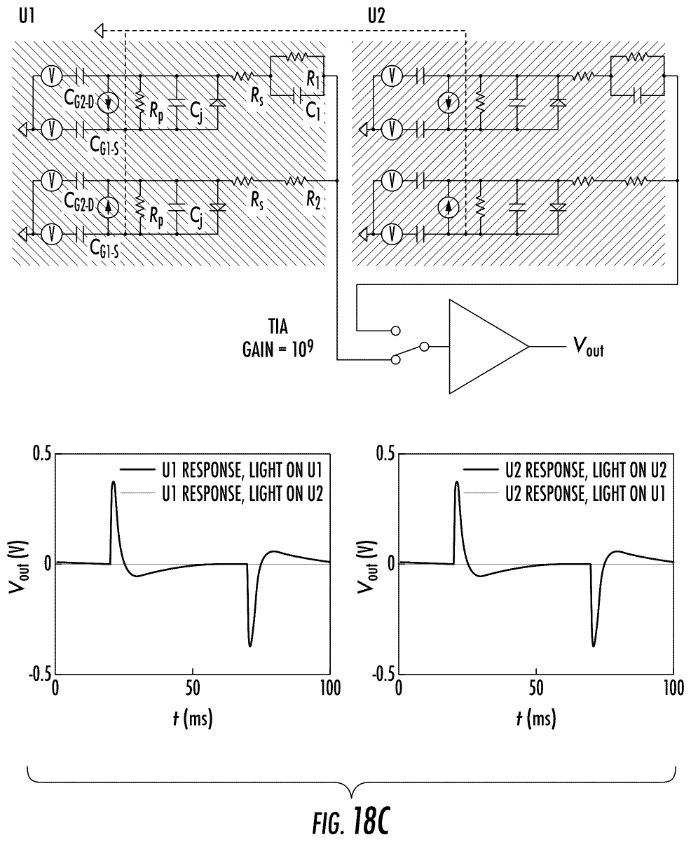

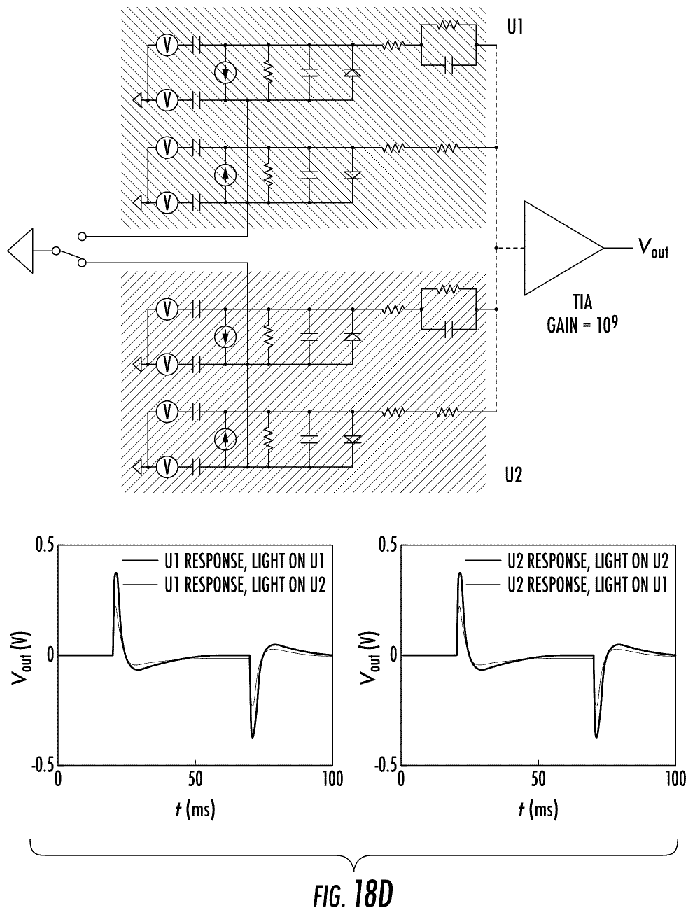

As the key figure-of-merit in array operation, we next examine the crosstalk among these four CUs by quantifying their spike amplitudes in the following (FIG. 3E):
I) For U12 and U22, we observe an acceptable level of crosstalk from U11 (likely from the edges of 530-nm light spots). Specifically, their 1^{st} [3^{rd}] spikes under condition I [II] (when 530-nm light is pulsed on [off]), as well as their two spikes under condition III, are all insignificant compared to the noise level from the baseline (Methods); their 3^{rd} [1^{st}] spikes under condition I [II] are smaller than those from U11 since only 590-nm pulses are applied to them.
II) For U21, we observe significant crosstalk from U11 in all four conditions, where U21 and U11 have nearly identical amplitudes of all spikes. This crosstalk is found to be related to the way U11 and U21 are connected in the crossbar structure. Specifically, we conduct further experiments by connecting two individual CUs in the way U12 and U21 are connected to Ull in the array, respectively (FIGS. 17A-17C). The results reaffirm a substantial crosstalk when these two CUs are connected in the way U21 and U11 are connected, in contrast to the negligible crosstalk when they are connected the other way around (further supported by simulation results in FIGS. 18A-18D, which may relate to the capacitance between G1[G2]- and S[D]-contacts). For this reason, this crosstalk could be avoided by replacing crossbar arrays with multiple rows of one-dimensional (1D) arrays for parallel readout; in each 1D array, all CUs are connected the way U12 and U11 are connected).

Importantly, our data suggest that the in-sensor CU array can indeed parallelize analog event detection. Such capability is achieved with zero static power because we short-circuit the branches in all CUs, and with a >30% FF due to our compact modular design (FIG. 1A). For these reasons, our CU array may represent a compact, low-power event detection technology.

Gate-tunable analog in-sensor edge detection at single-kernel levels: After demonstrating the use of α-Si PDs for event sensing, we now change to showcase their capability for analog in-sensor processing of spatial visual information by examining their promise for large-scale edge detection. Edge detection is one of the most basic building blocks for complex algorithms used in imaging processing. To date, it has been achieved by processing CMOS-imager collected data using GPU³², FPGA²², or in-pixel analog-computing circuits¹². Nonetheless, these state-of-the-art strategies in the electrical domain are often numerically intensive and need to boost their performance at the expense of power consumption or chip areas. Optical-domain solutions^{48,49}, on the other hand, are noted for their rapid operation and low power operation, yet often requiring meta-layers made of sub-μm sized features with low fabrication tolerance. To this end, in-sensor convolutional filtering has risen as a bio-inspired approach that circumvents the aforementioned limitations, whose multiply-accumulate computations via image kernels mimic the way the human retina uses to extract edge information^{9,11,13,27}. This strategy has been recently demonstrated by silicon²⁹ and 2D-material^{13,27} based individual kernels, which however are often built with large dimensions and require serial scanning across the image without the parallelism needed for large-scale edge detection³³.

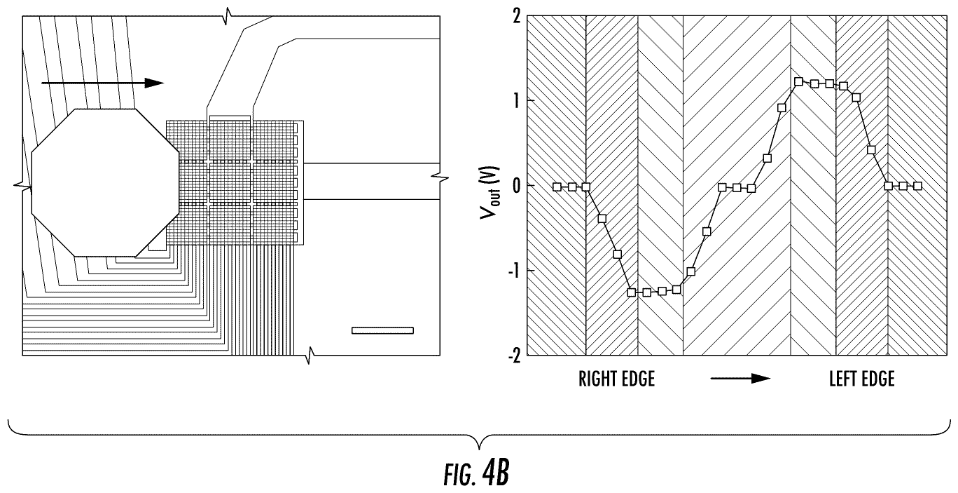

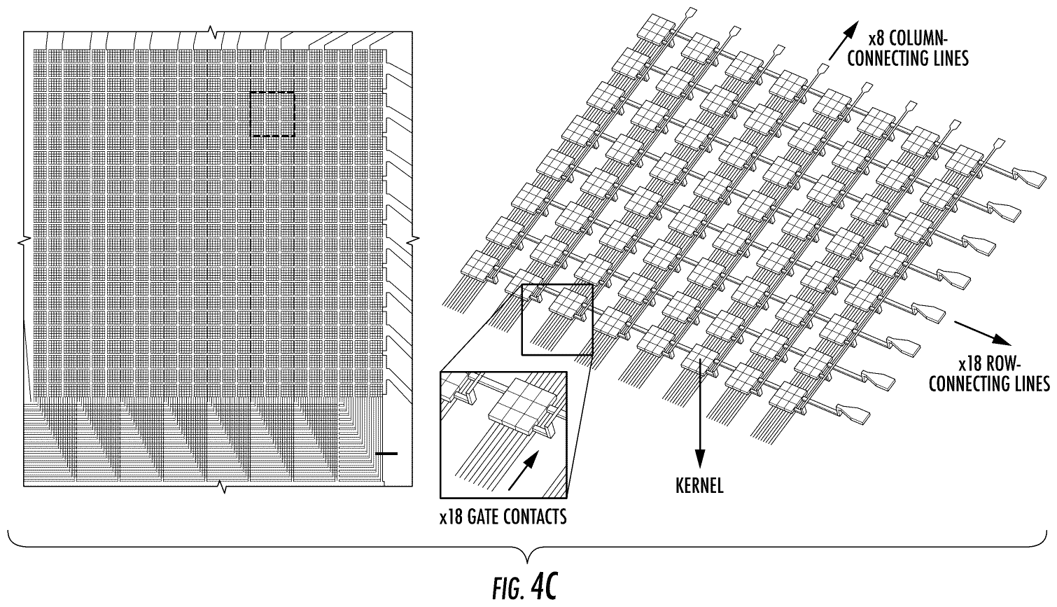

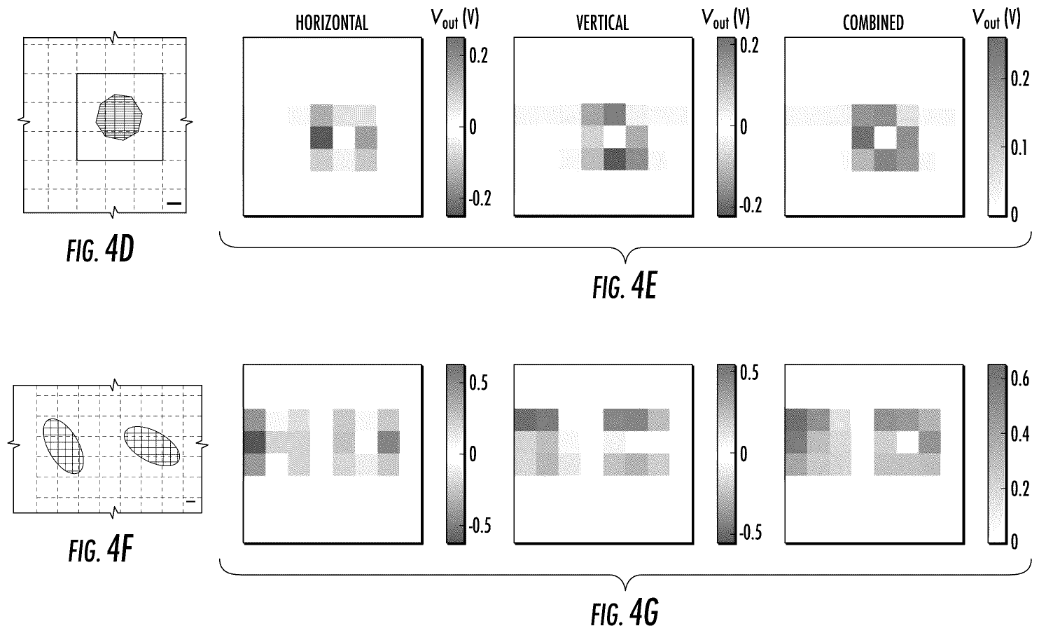

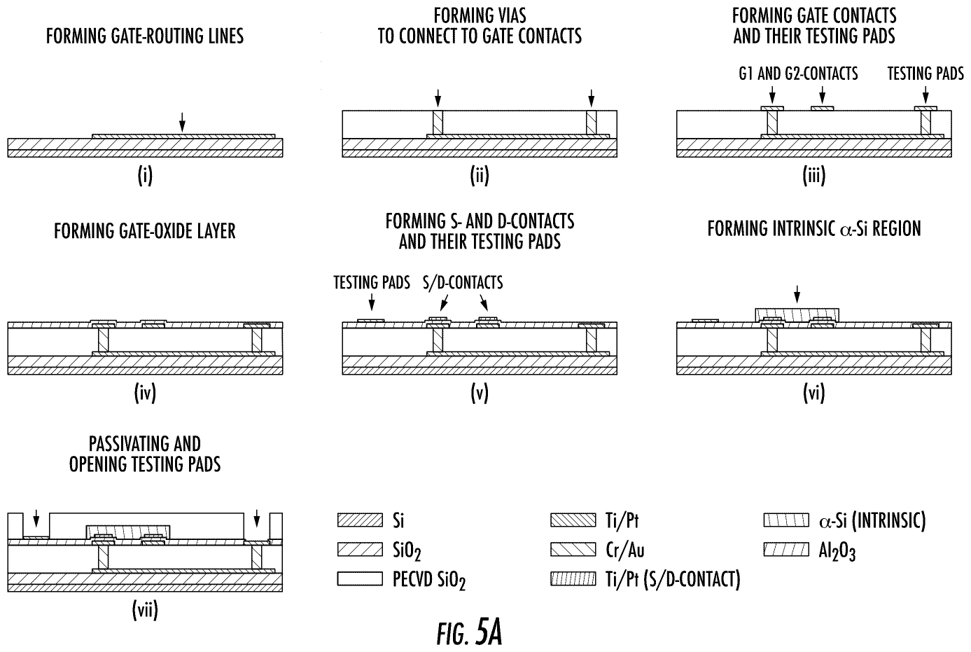

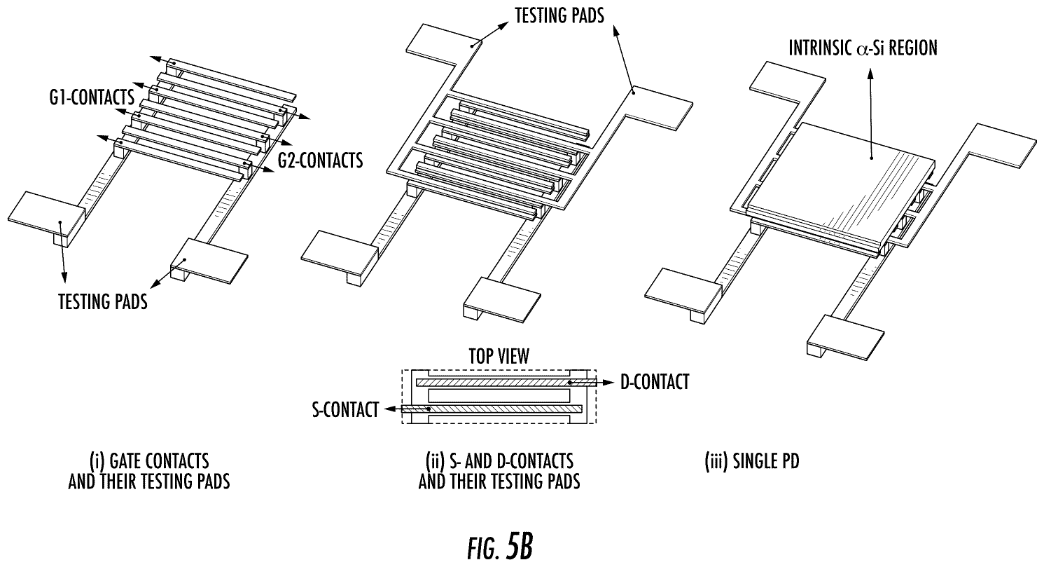

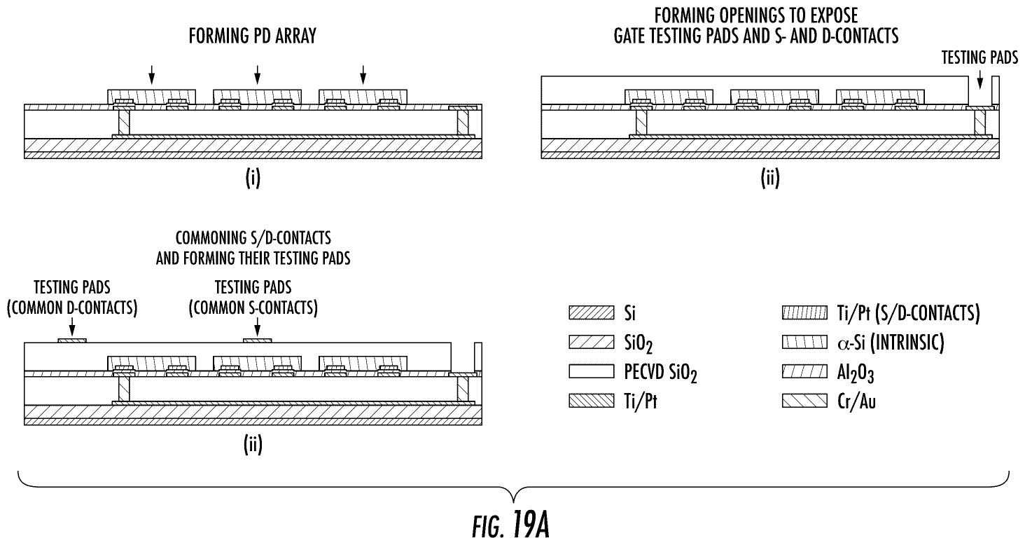

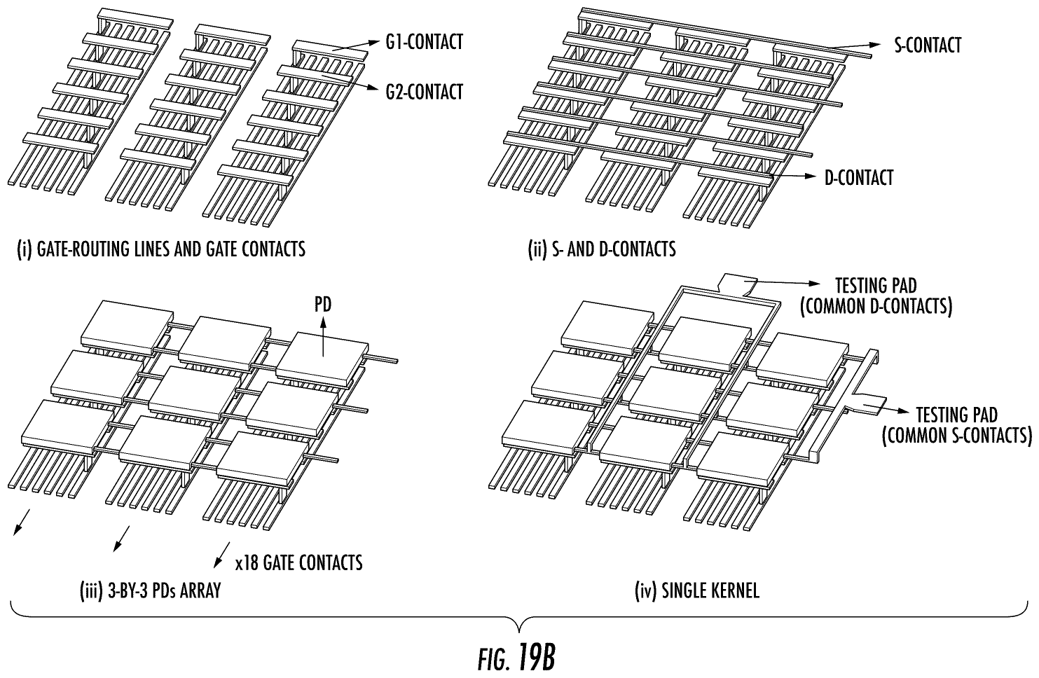

To address this unmet need, here we parallelize 3-by-3 PD arrays as one in-sensor kernel for edge detection (FIGS. 19A and 19B). Specifically, we common the S-[D-] contacts of all PDs and route them to a testing pad; a total of nine G1- and nine G2-contacts across the array routed to eighteen independent testing pads through vias. By gating these nine PDs with different Vₚ values (i.e. programming their Rₚₕ), we are able to measure the sum of their Rₚₕ-programmed Iₚₕ as the kernel readout (2/ph), which is then fed to the TIA for a voltage output Vₒᵤₜ (FIG. 4A). To demonstrate in-sensor edge detection, here we configure the kernel as a horizontal Prewitt filter by programming the photoresponse of three columns of PDs—C1, C2, and C3 in FIG. 4B—to be negative, zero, and positive, respectively (see Ip values in FIG. 27). This configuration will result in a non-zero kernel output when there is a gradient of P_{light} applied to these three columns, thereby detecting the edges of an object.

Next, we move the light spot through the aperture of a microscope (dimension ˜250 μm, P_{light}=530 mW/cm² at 550/15 nm) sequentially across the C1-C3. Along this trajectory, the kernel experiences a change in the gradient of P_{light}; its readout Vₒᵤₜ is collected at a step of ca. one-third of one column width (˜23 μm). Correspondingly, we observe the following trends: I) Vₒᵤₜ starts to decrease (Vₒᵤₜ=0 when the kernel is in the dark) as the light spot enters C1, since the right edge of the light spot induces negative Iₚₕ; II) Vₒᵤₜ stays at the negative maximum until the light spot enters C3, since the light illumination on C2 generates zero Iₚₕ; III) Vₒᵤₜ increases back to zero as the light spot enters C3, since the light illumination on C3 generates positive Iₚₕ; IV) Vₒᵤₜ stays at zero until light spot leaves C3, since ΣIₚₕ from all three columns is canceled out to be zero (absence of edges). Thereafter, due to similar reasons, Vₒᵤₜ increases from zero when the light spot leaves C1, stays at a positive maximum until the light spot leaves C2, and decreases back to zero when the light spot leaves C3. In sum, these results clearly demonstrate the edge detection of a horizontally-moving light spot.

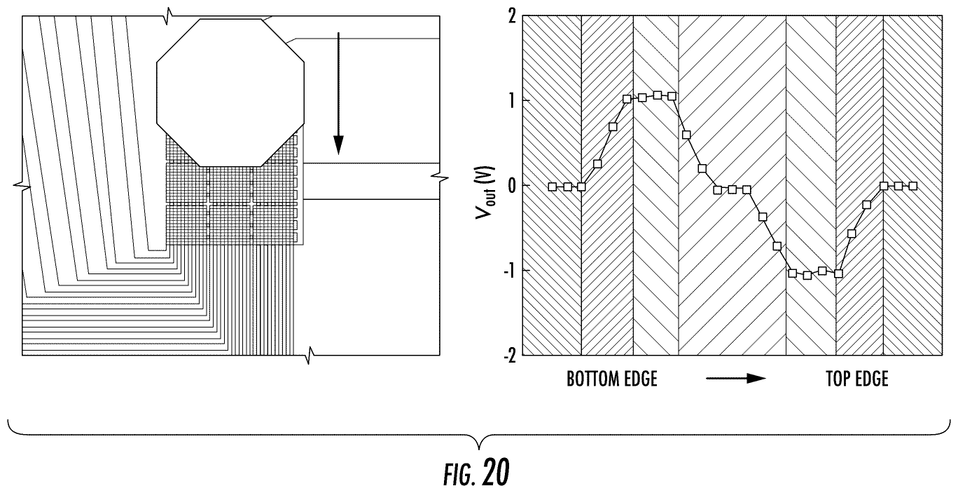

Moreover, we test the reconfigurability of our kernel by re-programming the Rₚₕ of three rows of the array to be positive, zero, and negative (see Vₚ values in FIG. 27). The results show that our re-configured kernel is able to work as a vertical Prewitt filter to detect the edge of a vertically moving light spot (FIG. 20).

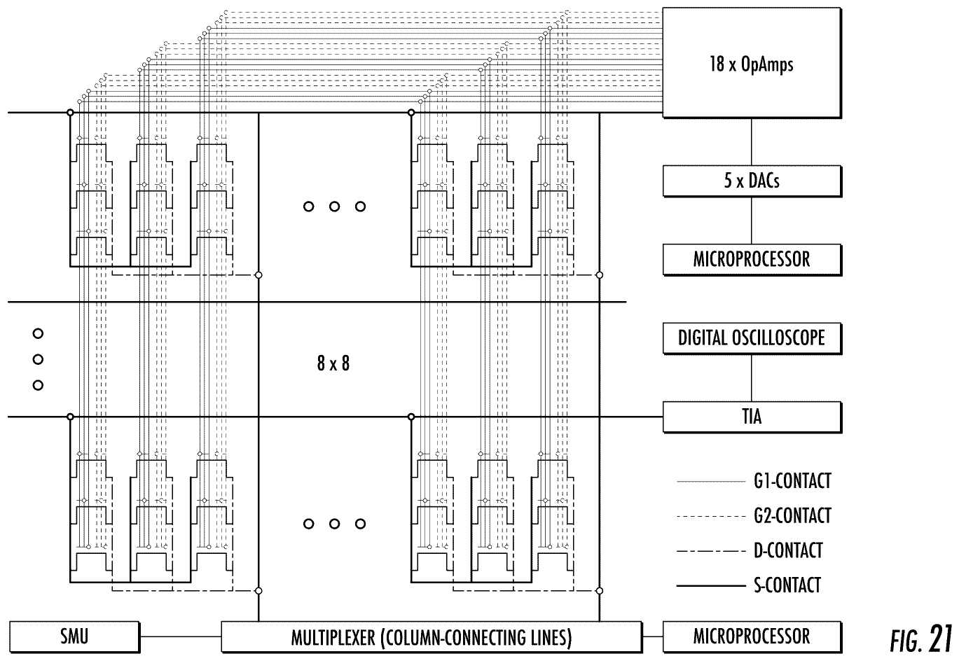

Gate-tunable analog in-sensor edge detection at kernel-array levels: Leveraging the scalability and modular design of our α-Si PDs, we then extend our studies to parallelized edge detection with a kernel array, which may prove beneficial for time-intensive and/or data-intensive applications (e.g., autonomous driving, medical imaging). Specifically, we take one eighteen-gate kernel (nine G1- and nine G2-contacts) as the functional unit to build an eight-by-eight cross-barred kernel array (composed of 576 PDs). In this array structure (FIG. 4C), sixty-four kernels are routed to eight column-connecting lines and eight row-connecting lines; all kernels share the same eighteen-gate control (e.g. wiring a total of sixty-four G1-contacts from the PDs placed in the first row and first column of each kernel) by gate routing layers underneath the PDs (FIG. 21). The resulting 100% yield array shows good uniformity of photoresponse among kernels (FIG. 22), and is connected to off-chip multiplexers for parallel readout.

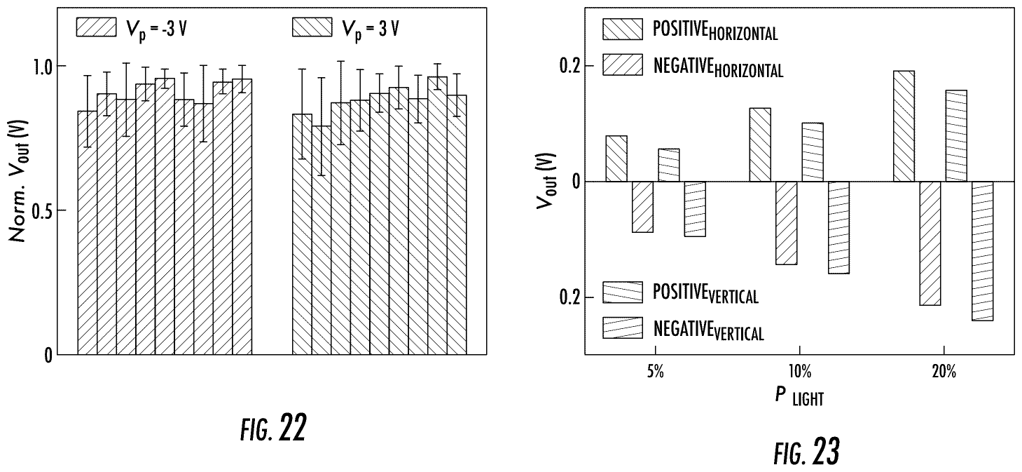

To demonstrate parallel in-sensor edge detection, we configure all sixty-four kernels in the array first as a horizontal Prewitt filter and then as a vertical Prewitt filter. The heat maps (i.e., contour plots) of the array readout (Vₒᵤₜ) under the two filters are sequentially squared, summed, and square-rooted to generate the heat map that combines the edges detected along both directions (i.e. combined map). Accordingly, we test the array performance by a light spot in the shape of the aperture in a microscope (diameter ˜300 μm). This light spot gets one kernel being fully illuminated, with eight adjacent kernels being partially illuminated (see FIG. 4D). The calculated combined map of Vₒᵤₜ (subtracted by values measured in the dark, FIG. 4E) shows non-zero Vₒᵤₜ values in the eight adjacent kernel devices, and a zero Vₒᵤₜ of the centered kernel, correctly marking our expected edge positions of the light spot. It is again noted that these Vₒᵤₜ values increase with P_{light} (FIG. 23), reaffirming the linearity of our PD-based arrays for analog in-sensor edge detection. Taking one step further, our array is also able to simultaneously detect the edges of multiple objects, provided here by two cell-like light spots defined by a shadow mask (FIG. 4F and 4G).

In sum, these results suggest that our kernel array is able to achieve parallel detection of the edges in both single and multiple objects. Notably, our array consumes zero electrical power due to the short-circuited operation, and features a >90% FF due to the compact modular design. Therefore, these arrays could be viewed as a viable low-power edge-detection technology that can be built into an integrated chip form.

### DISCUSSION

We have presented two scalable in-sensor visual processor arrays based on a compact modular design of α-Si based dual-gate PDs: a two-by-two CU array and an eight-by-eight kernel array for multiplexed analog processing of temporal and spatial visual information (i.e. events and edges), respectively. Both arrays share the features of compactness (with 30% and 90% FFs) and low-power operation (zero electrical power consumption via short-circuited CUs/PDs), and furthermore lend themselves for large-scale visual processing due to their compatibility for CMOS integration. Our in-sensor processing strategy chosen here circumvents the latency and energy consumption spent over the exchange of redundant data at the device level. By programming the photoresponse of independent PDs in these arrays, we are capable of: I) parallelized analog processing of location-dependent events at sub-ms precision with gate-tunable array output; and II) parallelized analog processing of edges of multiple objects in the FOV, with programmable convolutional filtering controlled by the gate biases. Such array-level of analog in-sensor visual processing may shed light on smart sensing systems aimed at large-scale, data-intensive, and latency-sensitive computer vision tasks.

Moving forward, our analog in-sensor visual processor arrays can add to the advancement of multifunctional computer vision hardware that can process visual information with ultralow power consumption and high spatiotemporal resolutions. Moreover, their CMOS compatibility may allow them to be monolithically integrated with analog in-memory computing devices^{6,23,24,27,30,46,47}, which can form fully-integrated on-chip analog deep-learning neural network to offer near-real-time sensing, processing, and recognition of the visual targets^{50,51}. This integration approach could pave new ways in a broad range of machine vision applications, especially in scenarios that demand simultaneous processing of spatiotemporal information (e.g., biomedical imaging^{3,4} and autonomous driving¹). For instance, our fully integrated system may enable efficient extraction of the spatial attributes of cells, tissues, and organs (e.g., size, shape, location), and fast tracking of their dynamic activities with biological⁵² or medical⁵³ significance (e.g., Ca²⁺ fluxes, blood oxygenation). On the other hand, our technology may empower human-computer interaction applications (e.g., augmented reality, virtual reality)⁵⁴ and automated navigation systems^{1,50,55} that heavily rely on timely extracting both spatial information (e.g., target recognition) and temporal dynamics (e.g., the motion of fast-moving objects).

Finally, we remark a few steps to further optimize the performance of our in-sensor processor arrays. First, to mitigate the electrical crosstalk across the array, our event-detecting CUs could be built into multiple rows of 1D arrays (instead of a cross-barred array). Second, to avoid in-sensor computation errors, both CUs and convolutional kernels could be connected to selectors (e.g., switching transistors) in series to shut the sneaky current paths. Third, the temporal resolution of our CU array (t_{rise/fall}) is currently limited by RC values and the upper limit of our TIA bandwidth. A sub-μs resolution of event detection can be achieved by CU arrays integrated with smaller Rs and Cs, and those wired to high-bandwidth TIA circuits; such smaller RC values can also benefit the reduction of heat dissipation of the circuit. Fourth, the FF of our CU array is currently limited by the sizes of Rs and Cs. To circumvent this issue, we can increase FFs by stacking PDs on top of the RC elements and/or choosing smaller Rs and Cs⁴⁰ (FF can be ideally close to 1 when the sizes of Rs and Cs are no more than those of the PDs).

### METHODS

Device fabrication: In this work, we use: 1) sputtered Ti/Pt layers (10/50 nm) to form G1-, G2-, S- and D-contacts, gate-routing lines, top electrodes of the C, and connection lines; 2) evaporated Cr/Au layers with a thickness of 10/300 nm [10/50 nm] for vias [the bottom electrode of the C]; 3) a 300 nm PECVD-SiO₂ layer to act as the passivate layer; 4) a 30 nm ALD-Al₂O₃ [15 nm ALD-HfO₂] layer as the gate oxide layer [dielectric layer for the capacitor], respectively; and 5) a 250 nm [100 nm] PECVD-based intrinsic [n-doped] α-Si layer to act as the light-absorbing region [integrated Rs].

For single PDs (Supplementary FIG. 1), we first pattern gate-routing lines on top of a SiO₂/Si substrate⁵⁶ (with a ca. 300 nm SiO₂ layer thermally grown on top of a p-doped Si substrate) and cover them with a passivation layer. Next, we form vias through the passivation layer by reactive ion etching (RIE) and metallization steps; G1- and G2-contacts and their testing pads are then deposited on top of vias to make connections. On top of them, we next sequentially form a gate-oxide layer²⁹, S/D-contacts together with their testing pads, and intrinsic α-Si regions for light absorption (patterned via RIE). Finally, we passivate the device and use RIE steps to open four testing pads that connect to G1-, G2, S-, and D-contacts.

For single CUs (Supplementary FIG. 6), we first form an integrated C by sandwiching a HfO2-based dielectric layer between a top electrode and a bottom electrode on top of a SiO₂/Si substrate. The top electrode is formed together with four gate-routing lines, from which we later build two identical PDs using aforementioned steps. Different from single-PDs though, here we form vias not only on gate routing lines (serve to later connect to gate contacts and their testing pads), but also on the top electrode of ((serve to later connect to two integrated Rs). Also, the S- and D-contacts of PDs are formed together with connection lines, which serve to wire the C, Rs, and PDs later as a 2PD-2R-1C circuit. Last but not least, after patterning the intrinsic α-Si regions of PDs, we pattern two Rs from an n-doped α-Si film (by RIE) on top of their pre-formed connection lines to complete the CU. Afterwards, we passivate the CU and use RIE steps to open the bottom electrode of C, the S-contacts of two PDs, and the four testing pads that are connected to their gate contacts. We then conduct a final metallization step to form connecting wires and testing pad (serve to connect to the bottom electrode of C and S-contacts), and metal features right above two Rs (i.e. light blockers) to avoid light-induced resistance change.

For the CU array (Supplementary FIG. 9), we form four identical CUs with the aforementioned steps. Different from single-CUs though, here we common the bottom electrodes of Cs in two CUs on the same column (U11+U21, U12+U22). We then passivate the device and use RIE steps to open S-contacts of CUs and bottom electrodes of Cs. Thereafter, we conduct a final metallization step to form light blockers, and wire S-contacts [bottom electrodes of Cs] to the row-[column-] connecting lines.

For single kernels (Supplementary FIG. 15), we form 9 PDs placed in a 3-by-3 array (a total of 18 independent gate contacts) using the same steps as single PDs. Next, we passivate the device and use RIE steps to open the testing pads that are connected to 18 gate contacts, as well as the S- and D-contacts of all 9 PDs. We then conduct a final metallization step to common 9 S- and 9 D-contacts via connecting wires and two testing pads, respectively.

For the kernel array (FIG. 4c), we form 64 identical kernels placed in an 8-by-8 array with the aforementioned steps. Different from single-kernels though, here we first common 18 independent gate-routing lines from 8 kernels in each column, and further wire the resulting 144 gate-routing lines to 18 global gate contacts (using vias, connecting wires, and the corresponding testing pads) that simultaneously control Vₚ values of all 64 kernels. Moreover, we common the S-contacts of 8 kernels in the same row, leading to a total of 8 independent row-connecting lines; in contrast, the D-contacts of all 64 kernels are still separated. Afterwards, we passivate the device and use RIE steps to open the testing pads that connect to 18 global gate contacts, the 8 row-connecting lines, and the 64 D-contacts. We then conduct a final metallization step to: 1) common 8 D-contacts in each column and wire them via 8 column-connecting lines and their testing pads; and 2) connect 8 row-connecting lines (wired to S-contacts) to 8 testing pads, respectively.

Device characterization: Single PDs are fully characterized by a semiconductor device parameter analyzer (Keysight B1500A), which serves to offer the biases of their G1-, G2-, S- and D-contacts via four independent manipulators.

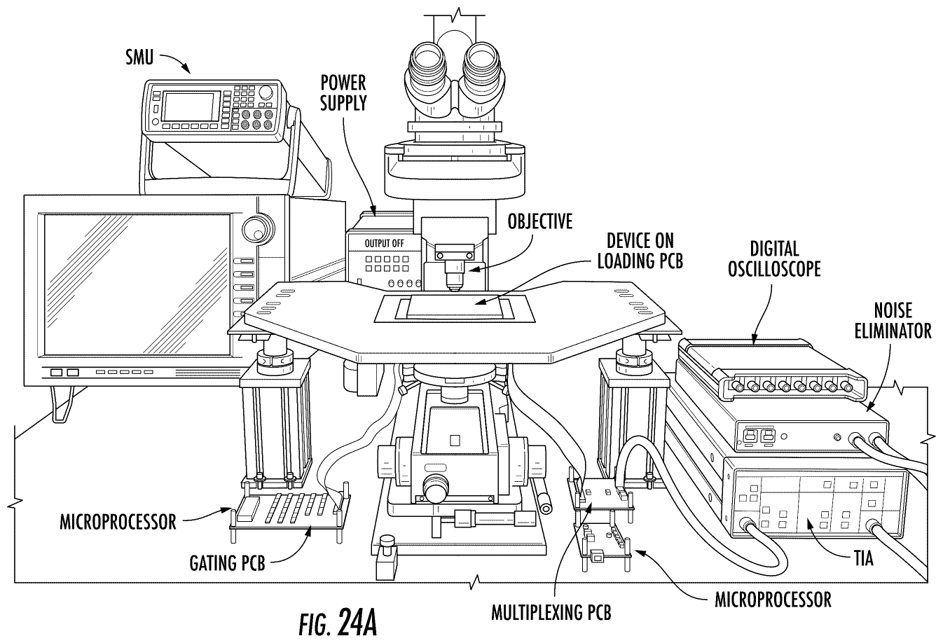

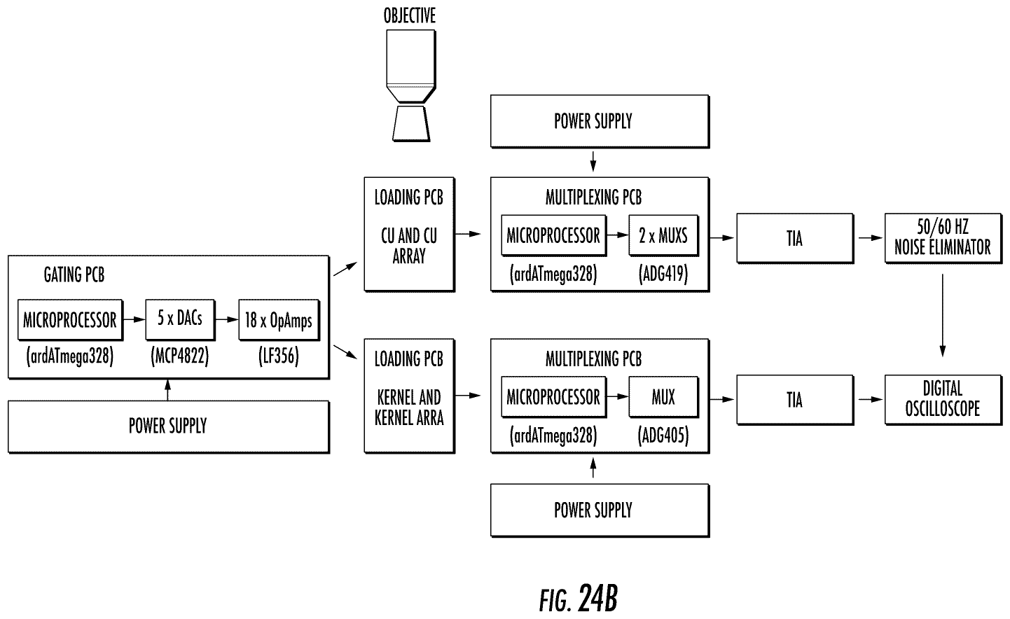

Single CUs or the CU arrays are first wire-bonded onto a loading printed circuit board (PCB, see FIGS. 24A and 24B), which is then wired to a gating PCB and a multiplexing PCB (both PCBs are powered by a power supply, Keysight E3631A). The gating PCB offers eighteen independent gate biases via microprocessor-controlled (ardATmega328) digital-to-analog convertors (MCP4822) and eighteen operational amplifiers (LF356, offset and amplify the output range); the microprocessor is set to gradually ramp Vₚ values at 0.15 V/s to avoid a large transient current that may cause oxide breakdown. The multiplexing PCB, on the other hand, serves to select the CU (either single CUs or one CU from the CU array) by two multiplexers (TI ADG419) that are controlled by another external microprocessor. For each selected CU, we bias the S-contacts of two PDs at 0 V with a source-measurement unit (SMU, Keysight 2902A), and connect the bottom electrode of C to the positive input of a TIA (Stanford Research System SR570, high bandwidth mode, gain=2×10⁸ V/A), whose negative input is biased at OV to convert the short-circuited branch current to Vₒᵤₜ values. The TIA output is then fed into a Hum bug noise eliminator (A-M Systems) to remove the 50/60 Hz noise, followed by a digital oscilloscope (Pico4824) to sample the filtered Vₒᵤₜ traces at 10 KHz.

Single kernels or the kernel arrays are first wire-bonded onto another loading PCB, which is then wired to the gating PCB (the same one used for CUs) and another multiplexing PCB that are powered by the same power supply. The gating PCB is operated the same way as the CU testing to offer 18 independent gate biases. On the other hand, we use one multiplexer (TI ADG405) on the multiplexing PCB to select the column-connecting line of the select kernel (note: single kernels are viewed as a 1-by-1 array here) via the external microprocessor and bias it at 0 V via the SMU; the row-connecting line of the select kernel is connected to the TIA (low noise mode, gain=2×10⁹ V/A), followed by the digital oscilloscope to sample the Vₒᵤₜ traces at 1 kHz.

Optical setup: During our experiments, we use an upright microscope (Nikon FN1) equipped with a Zyla4.2 plus sCMOS (scientific complementary metal-oxide semiconductor) camera (Andor, USB 3.0) and a SPECTRA X light engine (Lumencor) to: 1) take device images; 2) align the light spot to the device; and 3) provide 550/15 nm illumination patterns through a CFI60 Plan Achromat 10× objective lens (NA=0.25, Nikon). We also use two fiber-coupled LED (Thorlabs, M539F2 and M595F2) to provide 530 nm and 595 nm illumination, respectively.

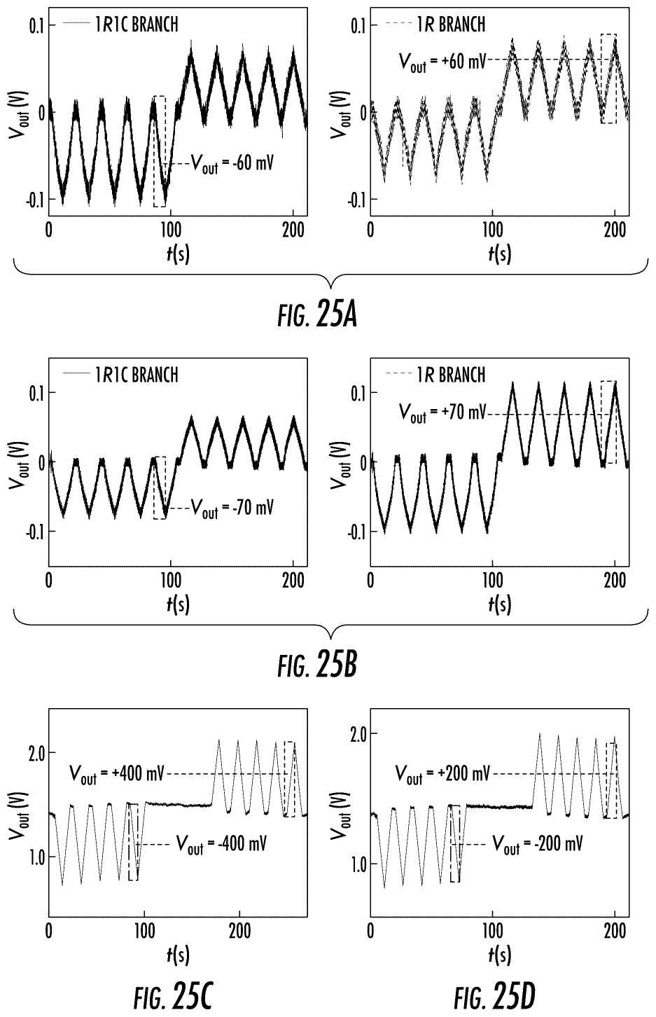

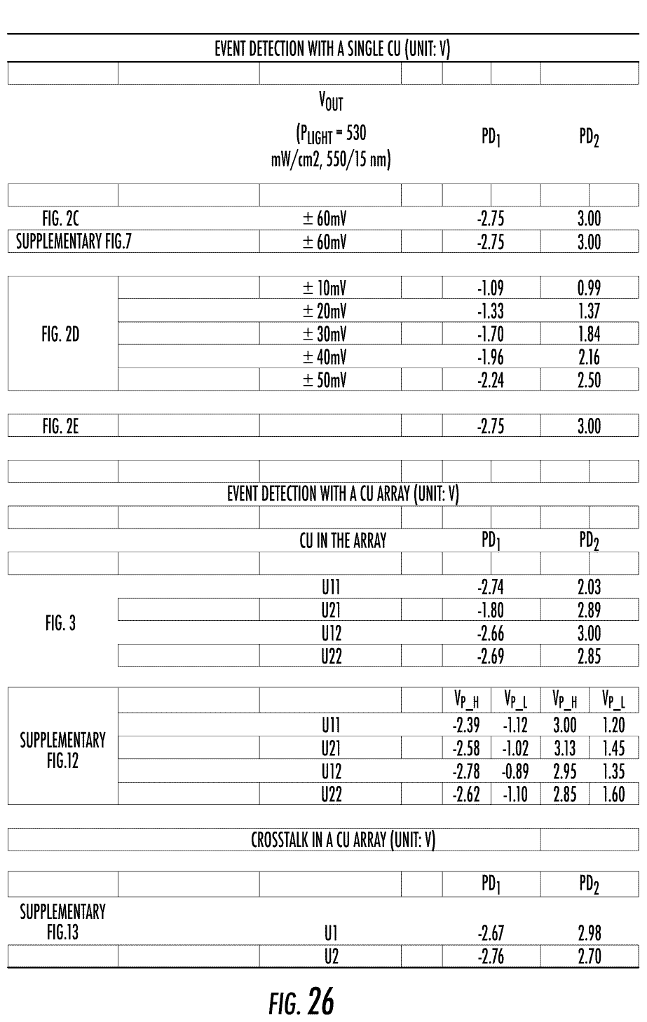

We test individual PDs in a CU by spatially confining the 550/15 nm illumination patterns (see FIGS. 11, 13A, 13B, 25A, and 25b). For the testing of CU arrays, we spatially confine the 530-nm illumination to U11 only (FIG. 3). For single-kernel experiments (FIG. 4B) and the kernel-array experiments in FIGS. 4D, 4E, we shape the light spot by the aperture of the microscope. For the kernel-array experiments in FIGS. 4F, 4G, we place a shadow mask—made of Pt/SU8 layers (300 nm/2 μm) patterned on a coverslip—face down onto the kernel array; this way we are able to illuminate two separate regions on the array.

Circuit simulation: We conduct circuit simulation under the LTspice environment. Specifically, we model the simplified equivalent circuit of PDs with a current source, an ideal diode, a junction resistor (Rₚ), a junction capacitor (Cⱼ), a series resistor (Rₛ), a parasitic capacitor existing between G1- and S-contacts (C_{G1-S}), and a parasitic capacitor existing between G2- and D-contacts (C_{G2-D})⁵⁷. In this work, we set these resistor values in two different approaches: 1) Rₚ is estimated from the slope of the I_{S}-V_{S} curve at V_{S}=0 (measured in dark, FIG. 1B)⁵⁸, while Rₛ is neglected by assuming Rₛ<<Rₚ; and 2) both Rₚ and Rs are estimated from the I_{S}-V_{S} curve in FIG. 1B using the Shockley model reported before³⁵. On the other hand, the value of Cⱼ is estimated from a quasi-static capacitance-voltage curve (QSCV, by B1500A) measured between S- and D-contacts of the PD with Vₚ being biased at 2.5 V (by gating PCB). Finally, the value of C_{GI-S} [C_{G2-D}] is estimated from the QSCV curve measured between G1- and S-contacts [G2- and D-contacts] of the PD with the G2- and D-contacts [G1- and S-contacts] being floated.

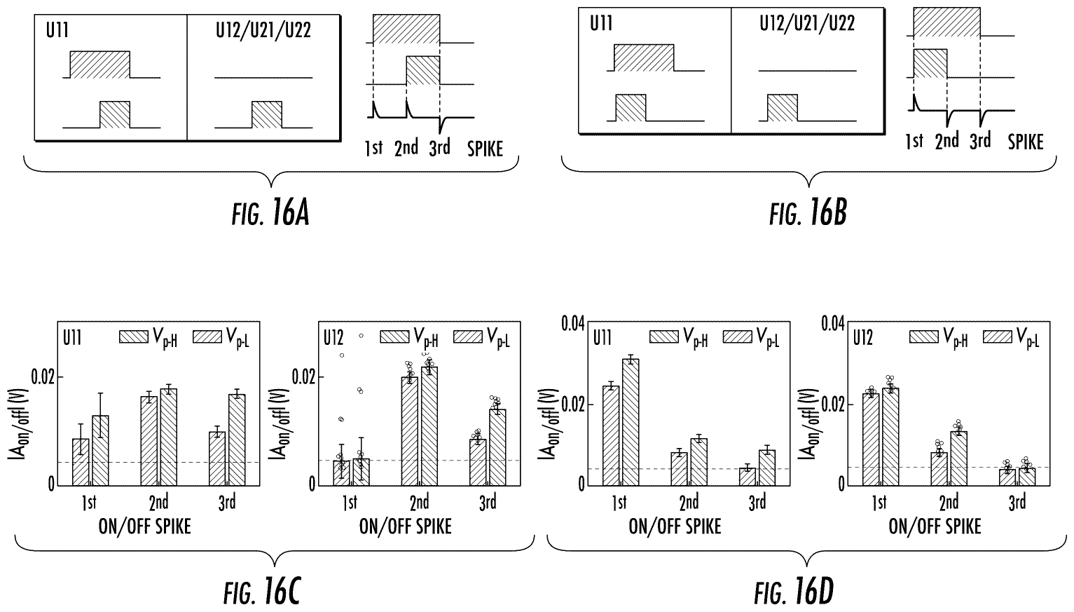

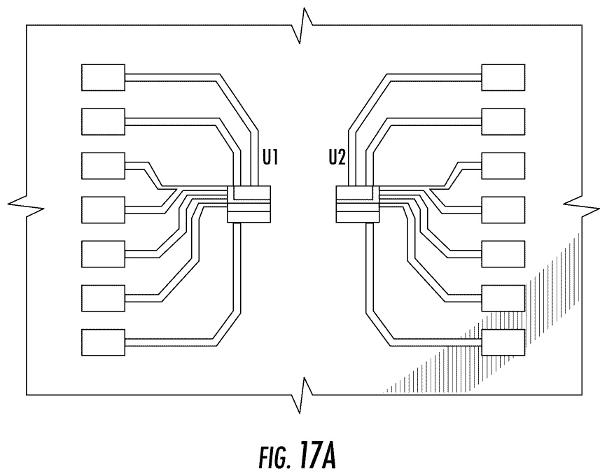

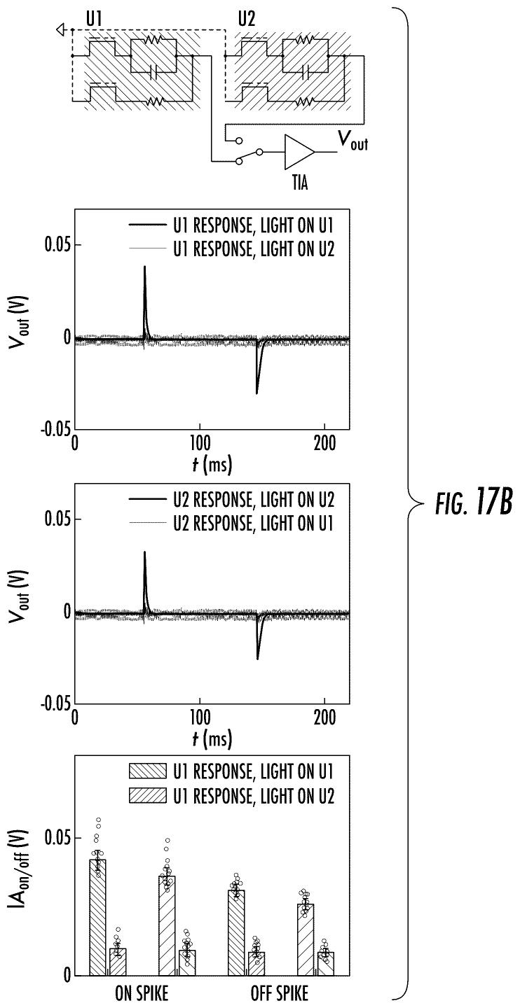

Data analysis: The values of A_{on/off} are obtained by subtracting the positive/negative maximum of the Vₒᵤₜ traces by the 10-point average of the baseline data from the 1-ms window right before each light pulse. The noise level in FIG. 3E [FIG. 16C] is defined as three times the S.D. in the baseline (measured from 1-s data right before the first light pulse and averaged by four CUs [averaged when each CU is biased at two different Vₚ values] in the array).

It would be appreciated by those skilled in the art that various changes and modifications can be made to the illustrated embodiments without departing from the spirit of the present invention. All such modifications and changes are intended to be within the scope of the present invention except as limited by the scope of the appended claims.

### REFERENCES

All referencese incorporated herein by reference in their entirety.
1. Jayachandran, D. et al. A low-power biomimetic collision detector based on an in-memory molybdenum disulfide photodetector. Nat. Electron. 3, 646-655 (2020).
2. Peters, B. & Kriegeskorte, N. Capturing the objects of vision with Neural Networks. Nat. Hum. Behav. 5, 1127-1144 (2021).
3. Eliceiri, K. et al. Biological imaging software tools. Nat. Methods 9, 697-710 (2012).
4. Cabriel, C., Monfort, T., Specht, C. G. & Izeddin, I. Event-based vision sensor for fast and dense single-molecule localization microscopy. Nat. Photon. 17, 1105-1113 (2023).
5. Dudek, P. et al. Sensor-level computer vision with pixel processor arrays for agile robots. Sci. Robot. 7, eab17755 (2022).
6. Zhou, F. & Chai, Y. Near-sensor and in-sensor computing. Nat. Electron. 3, 664-671 (2020).
7. Chai, Y. In-sensor computing for machine vision. Nature 579, 32-33 (2020).
8. Zhu, S. et al. Hierarchies in Visual Pathway: Functions and Inspired Artificial Vision. Adv. Mater., 2301986 (2023).
9. Masland, R. H. The neuronal organization of the retina. Neuron 76, 266-280 (2012).
10. Greene, M. J., Kim, J. S. & Seung, H. S. Analogous convergence of sustained and transient inputs in parallel on and off pathways for retinal motion computation. Cell Rep. 14, 1892-1900 (2016).
11. Rodieck, R. W. The first steps in seeing (Sinauer Associates, Sunderland, 1998).
12. Hsu, T. H. et al. A 0.5-V real-time computational CMOS image sensor with programmable kernel for feature extraction. IEEE J. of Solid-State Circuits 56, 1588-1596 (2016).
13. Wang, C. Y. et al. Gate-tunable van der Waals heterostructure for reconfigurable neural network vision sensor. Sci. Adv. 6, 6173 (2020).
14. Zhou, F. et al. Optoelectronic resistive random access memory for neuromorphic vision sensors. Nat. Nanotechnol. 14, 776-782 (2019).
15. Lee, S., Peng, R., Wu, C. & Li, M. Programmable black phosphorus image sensor for broadband optoelectronic edge computing. Nat. Commun. 13, 1485 (2014).
16. Seo, S. et al. Artificial optic-neural synapse for colored and color-mixed pattern recognition. Nat. Commun. 9, 5106 (2015).
17. Lichtsteiner, P., Posch, C. & Delbruck, T. A. 128×128 120 dB 15 μs latency asynchronous temporal contrast vision sensor. IEEE J. Solid-State Circuits 43, 566-576 (2008).
18. Chen, J. et al. Optoelectronic graded neurons for bioinspired in-sensor motion perception. Nat. Nanotechnol. 18, 882-888 (2023).
19. Zhang, Z., Wang, S., Liu, C., Xie, R., Hu, W. & Zhou, P. All-in-one two-dimensional retinomorphic hardware device for motion detection and recognition. Nat. Nanotechnol. 17, 27-32 (2022).
20. Cottini, N., Gottardi, M., Massari, N., Passerone, R. & Smilansky, Z. A. 33 μW 64×64 pixel vision sensor embedding robust dynamic background subtraction for EVENT detection and scene interpretation. IEEE J. Solid-State Circuits 48, 850-863 (2013).
21. Posch, C., Serrano-Gotarredona, T., Linares-Barranco, B. & Delbruck, T. Retinomorphic event-based vision sensors: bioinspired cameras with spiking output. Proc. IEEE 102, 1470-1484 (2014).
22. Xu, Q., Varadarajan, S., Chakrabarti, C. & Karam, L. J. A distributed canny edge detector: algorithm and FPGA implementation. IEEE Trans. Image Process. 23, 2944-2960 (2014).
23. Li, C. et al. Analogue signal and image processing with large memristor crossbars. Nat. Electron. 1, 52-59 (2018).
24. Kim, K. H. et al. A functional hybrid memristor crossbar-array/CMOS system for data storage and neuromorphic applications. Nano Lett. 12, 389-395 (2012).
25. Wu, H., Yao, P., Gao, B. & Qian, H. Multiplication on the edge. Nat. Electron. 1, 8-9 (2018).
26. Kanopoulos, N., Vasanthavada, N. & Baker, R. L. Design of an image edge detection filter using the Sobel operator. IEEE J. Solid-State Circuits 23, 358-367 (1988).
27. Mennel, L., Symonowicz, J., Wachter, S., Polyushkin, D. K., Molina-Mendoza, A. J. & Mueller, T. Ultrafast machine vision with 2D material neural network image sensors. Nature 579, 62-66 (2020).
28. Roy, K., Jaiswal, A. & Panda, P. Towards spike-based machine intelligence with neuromorphic computing. Nature 575, 607-617 (2019).
29. Jang, H. et al. In-sensor optoelectronic computing using electrostatically doped silicon. Nat. Electron. 5, 519-525 (2022).
30. Wu, G. et al. Ferroelectric-defined reconfigurable homojunctions for in-memory sensing and computing. Nat. Mater. 22, 1499-1506 (2023).
31. Huang, P. et al. Neuron-inspired optical sensor array for high-accuracy static image recognition and dynamic trace extraction. Nat. Commun. 14, 6736 (2023).
32. Luo, Y. & Duraiswami, R. Canny edge detection on NVIDIA CUDA. IEEE Computer Society Conference on Computer Vision and Pattern Recognition Workshops (CVPRW), 1-8 (2008).
33. Chai, Y. Silicon photodiodes that multiply. Nat. Electron. 5, 483-484 (2022).
34. Pospischil, A., Furchi, M. M. & Mueller, T. Solar-energy conversion and light emission in an atomic monolayer p-n diode. Nat. Nanotechnol. 9, 257-261 (2014).
35. Buscema, M., Groenendijk, D. J., Steele, G. A., Van Der Zant, H. S. & Castellanos-Gomez, A. Photovoltaic effect in few-layer black phosphorus PN junctions defined by local electrostatic gating. Nat. Commun. 5, 4651 (2014).
36. Baugher, B. W., Churchill, H. O., Yang, Y. & Jarillo-Herrero, P. Optoelectronic devices based on electrically tunable p-n diodes in a monolayer dichalcogenide. Nat. Nanotechnol. 9, 262-267 (2014).
37. Van Berkel, C. & Powell, M. J. Resolution of amorphous silicon thin-film transistor instability mechanisms using ambipolar transistors. Appl. Phys. Lett. 51, 1094-1096 (1987).
38. Island, J. O., Blanter, S. I., Buscema, M., van der Zant, H. S. & Castellanos-Gomez, A. Gate controlled photocurrent generation mechanisms in high-gain In2Se3 phototransistors. Nano Lett. 15, 7853-7858 (2015).
39. Brandli, C., Berner, R., Yang, M., Liu, S. C. & Delbruck, T. A 240×180 130 db 3 μs latency global shutter spatiotemporal vision sensor. IEEE J.Solid-State Circuits 10, 2333-2341 (2014).
40. Finateu, T. et al. A 1280×720 back-illuminated stacked temporal contrast event-based vision sensor with 4.86 μm pixels, 1.066 GEPS readout, programmable event-rate controller and compressive data-formatting pipeline. IEEE International Solid-State Circuits Conference-(ISSCC), 112-114 (2020).
41. Posch, C., Matolin, D. & Wohlgenannt, R. A QVGA 143 dB dynamic range frame-free PWM image sensor with lossless pixel-level video compression and time-domain CDS. IEEE J. Solid-State Circuits 1, 259-275 (2010).
42. Li, Y. & Shen, G. Advances in optoelectronic artificial synapses. Cell Rep. Phys. Sci. 3, 101037 (2022).
43. Liu, K. et al. An optoelectronic synapse based on α-In2Se3 with controllable temporal dynamics for multimode and multiscale reservoir computing. Nat. Electron. 5, 761-773 (2022).
44. Zhou, Y. et al. A 2T2R1C vision cell with 140 dB dynamic range and event-driven characteristics for in-sensor spiking neural network. International Electron Devices Meeting (IEDM), 31.4.1-31.4.4 (2022).
45. Zhou, Y. et al. Computational event-driven vision sensors for in-sensor spiking neural networks. Nat. Electron. 6, 1-9 (2023).
46. Wang, H. Analog chip paves the way for sustainable AI. Nature 620, 731-732 (2013).
47. Ambrogio, S. et al. An analog-AI chip for energy-efficient speech recognition and transcription. Nature 620, 768-775 (2023).
48. Zhou, Y., Zheng, H., Kravchenko, I. I. & Valentine, J. Flat optics for image differentiation. Nat. Photon. 14, 316-323 (2020).
49. Zheng, H., Liu, Q., Zhou, Y., Kravchenko, I. I., Huo, Y. & Valentine, J. Meta-optic accelerators for object classifiers. Sci. Adv. 8, p.eabo6410 (2022).
50. Chen, Y. et al. All-analog photoelectronic chip for high-speed vision tasks. Nature 623, 48-57 (2023).
51. Feldmann, J., Youngblood, N., Wright, C. D. Bhaskaran, H. & Pernice, W. H. P. All-optical spiking neurosynaptic networks with self-learning capabilities. Nature 569, 208-214 (2019).
52. Grewe, B. F., Langer, D., Kasper, H., Kampa, B. M. & Helmchen, F. High-speed in vivo calcium imaging reveals neuronal network activity with near-millisecond precision. Nat. Methods 7, 399-405 (2010).
53. Göröcs, Z. & Ozcan, A. On-chip biomedical imaging. IEEE Rev. Biomed. Eng. 6, 29-46 (2013).
54. Rautaray, S. S. & Agrawal, A. Vision based hand gesture recognition for human computer interaction: a survey. Artif. Intell. Rev. 43, 1-54 (2015).
55. Chen, R. et al. Breaking the temporal and frequency congestion of LiDAR by parallel chaos. Nat. Photon. 17, 306-314 (2023).
56. Sun, F., Xiong, Z., Park, J. & Xu, G. Close-Packed PEDOT: PSS-Coated Graphene Microelectrodes for High-Resolution Interrogation of Neural Activity. IEEE Trans. Electron Devices 68, 3080-3086 (2021).
57. Taur, Y. Analytic solutions of charge and capacitance in symmetric and asymmetric double-gate MOSFETs. IEEE Trans. Electron Devices 48, 2861-2869 (2001).
58. Banerjee, S. & Anderson, W. A. Temperature dependence of shunt resistance in photovoltaic devices. Appl. Phys. Lett. 49, 38-40 (1986).

What is claimed is:

1. A computer vision system, comprising:
a first scalable in-sensor visual processing array configured and arranged for event sensing; and
a second scalable in-sensor visual processing array configured and arranged for edge detection.

2. The system of claim 1, wherein the first scalable in-sensor visual processing array comprises a plurality of dual-gate amorphous-silicon photodiodes.

3. The system of claim 1, wherein the second scalable in-sensor visual processing array comprises a plurality of dual-gate amorphous-silicon photodiodes.

4. The system of claim 1, wherein the first scalable in-sensor visual processing array is arranged in a grid pattern and built monolithically using silicon-based fabrication processes.

5. The system of claim 1, wherein the second scalable in-sensor visual processing array is arranged in a grid pattern and built monolithically using silicon-based fabrication processes.

6. A computing unit for an in-sensor visual processing array, comprising:
a first gate:
a first photodiode;
a first resistor;
a first capacitor;
the first resistor and first capacitor monolithically built together with, and electrically connected to, the first photodiode in parallel.

7. The computing unit of claim 6, further comprising:
a second gate, comprising:
a second photodiode; and
a second resistor electrically connected to the second photodiode;
wherein the first gate and second gate second are monolithically built together with, and electrically connected in parallel.

8. The computing unit of claim 6, wherein the first photodiode is an amorphous-silicon photodiode.

9. The computing unit of claim 7, wherein the second photodiode is an amorphous-silicone photodiode.

10. An in-sensor computer vision system, comprising:
a plurality of computing units, comprising dual-gate amorphous-silicone photodiodes;
the computing units configured and arranged in a grid pattern.

11. The system of claim 10, wherein the plurality of computing units is further configured and arranged into a first visual processing array configured and arranged for event sensing, and a second visual processing array configured and arranged for edge detection.

12. The system of claim 10, wherein each computing unit comprises a first gate and a second gate electrically connected in parallel.

13. The system of claim 12, wherein the first gate comprises: a first photodiode, a first resistor, and a first capacitor, the first resistor and first capacitor electrically connected to the first photodiode in parallel.

14. The system of claim 12 wherein the second gate comprises: a second photodiode and a second resistor electrically connected to the second photodiode.

15. A method of making an in-sensor computer vision system, via deposition and etching techniques, comprising:
forming a silicon-based substrate;
forming photodiode gate routing lines on the substrate;
depositing a passivation layer over the gate routing lines and substrate;
etching vias through the passivation layer to form contact placement areas;
forming gate contacts on the contact placement areas, making connections to the gate routing lines;
depositing a gate oxide layer to form a capacitor;
etching α-Si areas over the gate routing lines to form light absorbing regions for the photodiode; and
forming S and D contacts on the gate routing lines of the photodiode via etching and metallization;
whereby a computing unit is formed.

16. The method of claim 15, further comprising forming an array of electrically connected computing units.

17. The method of claim 15, wherein the silicon-based substrate is SiO₂.

18. The method of claim 15, wherein the gate routing lines comprise Ti/Pt layers having thickness of about 10/50 nm.

19. The method of claim 15, wherein the vias comprise layers of Cr/Au of about 10/300 nm.

20. The method of claim 15, wherein the passivate layer comprises PECVD-SiO₂ of about 300 nm.

21. The method of claim 15, wherein the gate oxide layer comprises ALD-Al₂O₃ and ALD-HfO₂ of about 30 nm and 15 nm, respectively.

22. The method of claim 15, wherein the light absorbing regions comprise PECVD-based intrinsic α-Si of about 100 nm.
